(19) United States
(12) Patent Application Publication
(10) Pub. No.: US 2016/0064253 A1
(43) Pub. Date: Mar. 3, 2016

(54) METHOD FOR MANUFACTURING A SEMICONDUCTOR DEVICE

(71) Applicant: Renesas Electronics Corporation, Tokyo (JP)

(72) Inventor: Tohru Kumamoto, Gunma (JP)

(21) Appl. No.: 14/829,628

(22) Filed: Aug. 18, 2015

(30) Foreign Application Priority Data
Aug. 28, 2014 (JP) 2014-174470

(51) Int. Cl. H01L 21/48; H01L 23/495; H01L 23/31

(52) U.S. Cl. CPC H01L 21/4842; H01L 23/3107; H01L 23/49541

(57) ABSTRACT

A method for manufacturing a semiconductor device, which improves the mounting reliability of the semiconductor device. A plurality of leads are sandwiched and cut between an upper mold and a lower mold. There are gaps between a post (guide rail) and a bush (rail holder) which control sliding movement of the upper mold. After the leads are sandwiched between the upper mold and the lower mold and before they are cut, the positional relation between the lower mold supporting the leads and the upper mold in contact with the lower surfaces of the leads is adjusted.

### CROSS-REFERENCE TO RELATED APPLICATIONS

The disclosure of Japanese Patent Application No. 2014-174470 filed on Aug. 28, 2014 including the specification, drawings and abstract is incorporated herein by reference in its entirety.

### BACKGROUND

The present invention relates to a semiconductor device manufacturing technique for cutting leads protruding, for example, from a sealing member for sealing a semiconductor chip.

Japanese Unexamined Patent Application Publication No. 2007-273729 and Japanese Unexamined Patent Application Publication No. Hei 11(1999)-31774 describe that in the step of cutting a lead using a die and a punch, the clearance between the die and punch is controlled.

Japanese Unexamined Patent Application Publication No. 2008-16571 describes that after cutting a lead, the elastic deformation of the lead is removed, thereby preventing the end face of the lead from being scraped by a cut punch.

Japanese Unexamined Patent Application Publication No. 2000-216318 describes the formation of an arc clear (escape) part at the end of a die and Japanese Unexamined Patent Application Publication No. Hei 11(1999)-31774 describes a lead cutter with a chamfered taper part at an end of a punch.

Japanese Unexamined Patent Application Publication No. Hei 5(1993)-21683 describes the shape of a lead which improves the reliability of solder junction in mounting.

### SUMMARY

The present inventors have been exploring techniques which improve the performance of a semiconductor device. In an effort in this direction, the inventors examined a technique which enhances the mounting reliability of a semiconductor device by increasing the accuracy in simultaneously cutting a plurality of leads exposed from a sealing member for sealing a semiconductor chip.

The above and further objects and novel features of the invention will more fully appear from the following detailed description in this specification and the accompanying drawings.

According to one aspect of the present invention, there is provided a method for manufacturing a semiconductor device, which includes the step of sandwiching a plurality of leads between an upper and a lower mold and cutting them. There are gaps between a guide rail and a rail holder which control sliding movement of the upper mold. In the method, after the leads are sandwiched between the molds and before they are cut, the positional relation between the lower mold supporting the leads and the upper mold in contact with the lower surfaces of the leads is adjusted.

According to the present invention, the mounting reliability of a semiconductor device is improved.

### BRIEF DESCRIPTION OF THE DRAWINGS

FIG. 1 is a top view of a semiconductor device according to an embodiment;

FIG. 2 is a sectional view taken along the line A-A of FIG. 1;

FIG. 3 is a transparent plan view showing the internal structure of the semiconductor device shown in FIG. 1 as seen through its sealing member;

FIG. 4 is an enlarged sectional view showing the semiconductor device shown in FIG. 2 as mounted on a mounting board;

FIG. 5 is an enlarged sectional view of the tip of the outer lead part of one of the leads shown in FIG. 2;

FIG. 6 is a flowchart for explaining the assembly process of the semiconductor device described in reference to FIGS. 1 to 5;

FIG. 7 is an enlarged plan view of a lead frame provided in the step of providing a substrate as shown in FIG. 6;

FIG. 8 is an enlarged plan view showing a semiconductor chip mounted over a die pad of the lead frame shown in FIG. 7;

FIG. 9 is an enlarged plan view showing that the semiconductor chip and leads shown in FIG. 8 are electrically coupled through wires;

FIG. 10 is an enlarged plan view showing that a sealing member for sealing a semiconductor chip is formed in each of the device formation areas shown in FIG. 9;

FIG. 11 is an enlarged plan view showing that after making metal coatings on the exposed surfaces of the leads shown in FIG. 10 and cutting the leads, the leads are reshaped;

FIG. 12 is an enlarged plan view showing that the hanging leads shown in FIG. 11 are cut and the semiconductor device in each device formation area becomes an independent semiconductor device;

FIG. 13 is a flowchart showing details of the lead cutting step shown in FIG. 6;

FIG. 14 is a view for explaining the general structure of a lead cutter for cutting leads and how its moving parts work;

FIG. 15 is a plan view showing the planar positional relation between the post and bush shown in FIG. 14;

FIG. 16 is an enlarged side view showing a lead frame placed on the lead cutter in the step of placing a substrate as shown in FIG. 13;

FIG. 17 is an enlarged side view showing that the punches shown in FIG. 16 are in contact with leads in the step of contacting leads as shown in FIG. 13;

FIG. 18 is an enlarged side view showing that in the step of deforming leads as shown in FIG. 13, the leads are partially deformed;

FIG. 19 is an enlarged side view showing that in the alignment step as shown in FIG. 13, clearance distances between punches and dies have been adjusted;

FIG. 20 is an enlarged side view showing that in the step of making a shear surface as shown in FIG. 13, the leads are partially sheared;

FIG. 21 is an enlarged side view showing that in the step of making a fracture surface as shown in FIG. 13, the leads are cut by fracturing portions of the leads adjacent to their upper surfaces:

FIG. 22 is a bottom plan view of the upper mold of a lead cutter as a variation of the lead cutter shown in FIG. 14, in which a plurality of punches are fixed on the bottom of the upper mold;

FIG. 23 is a plan view showing the positional relation between the post and bush shown in FIG. 22 as a variation of the one shown in FIG. 15;

FIG. 24 is an enlarged plan view showing the planar positional relation between the punches and the dies with the upper mold shown in FIG. 22 placed over the lower mold;

FIG. 25 is an enlarged sectional view showing an end of the lead holding surface of a die and an end of the pressing surface of a punch, in which the die and punch are modified forms of the die and punch shown in FIGS. 16 to 21; and

FIG. 26 is an enlarged sectional view showing modified forms of the die and punch shown in FIG. 25.

### DETAILED DESCRIPTION

### Rules of Description in the Specification

The preferred embodiments of the present invention may be described separately in different sections as necessary or for convenience sake, but the embodiments described as such are not irrelevant to each other unless otherwise expressly stated. Regardless of the order in which they are described, one embodiment may be, in part, a detailed form of another, or one embodiment may be, in whole or in part, a variation of another. Basically, descriptions of the same elements or things are not repeated. In the preferred embodiments, when a specific numerical value is indicated for an element, the numerical value is not essential for the element unless otherwise expressly stated or unless theoretically limited to the numerical value or unless obviously the context requires the element to be limited to the specific value.

In description of a material or composition in an embodiment of the invention, the expression “X comprising A” does not exclude a material or composition which includes an element other than A unless otherwise expressly stated or unless obviously the context requires exclusion of another element. If the expression concerns a component, it means “X which contains A as a main component”. For example, the term “silicon member” obviously refers to not only a member made of pure silicon but also a member made of SiGe (silicon germanium) alloy or another type of multi-component alloy which contains silicon as a main component or a member which contains another additive. Similarly, for example, the terms “gold plating,” “Cu layer,” and “nickel plating” obviously refer to not only members of pure gold, Cu and nickel but also members made of multi-component materials which contain gold, Cu and nickel as main components, respectively.

Also, even when a specific numerical value or quantity is indicated for an element, the numerical value or quantity of the element may be larger or smaller than the specific numerical value or quantity unless otherwise expressly stated or unless theoretically limited to the specific value or quantity or unless the context requires the element to be limited to the specific value or quantity.

In this specification, the terms “plane surface” and “side surface” may be sometimes used. Here, on the assumption that the semiconductor element formation surface is a reference plane, a surface parallel to the reference plane is described as a plane surface and a surface crossing the plane surface is described as a side surface. In a side view, a direction which couples two plane surfaces spaced from each other is described as a thickness direction.

In this specification, the terms “upper surface” and “lower surface” are sometimes used. For semiconductor packages, various mounting methods are used. For example, there may be cases that when a semiconductor package is mounted, its upper surface is located below its lower surface. In this specification, the plane surface on which semiconductor chip elements are formed or the surface of a wiring board which includes a chip mounting surface is referred to as the upper surface and the surface opposite to the upper surface is referred to as the lower surface.

In all the drawings that illustrate an embodiment, the same or similar elements are designated by the same or similar reference signs or numerals and basically descriptions thereof are not repeated.

Regarding the accompanying drawings, hatching or the like may be omitted even in a cross section diagram if hatching may cause the diagram to look complicated or it is easy to distinguish the area concerned from an air gap. In connection with this, background contour lines may be omitted even for a closed hole in a plan view if the contour of the hole is apparent from an explanation, etc. Furthermore, even if a drawing does not show a cross section, hatching or a dot pattern may be added to clarify that the area concerned is not an air gap or to show the border of an area clearly.

### Embodiment

The technique of the embodiment described below may be widely used for semiconductor devices in which a plurality of leads protrude from a sealing member for sealing a semiconductor chip. The explanation given below assumes that the embodiment concerns a QFP (Quad Flat Package) semiconductor device in which leads protrude from each of the four sides of a quadrangular sealing member in plan view.

### <Semiconductor Device>

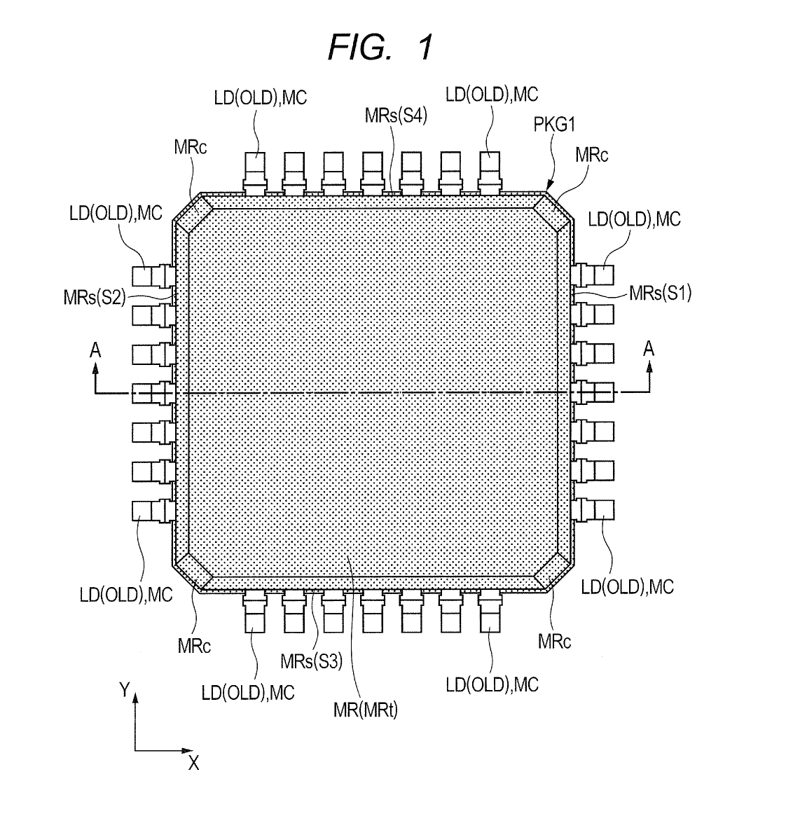

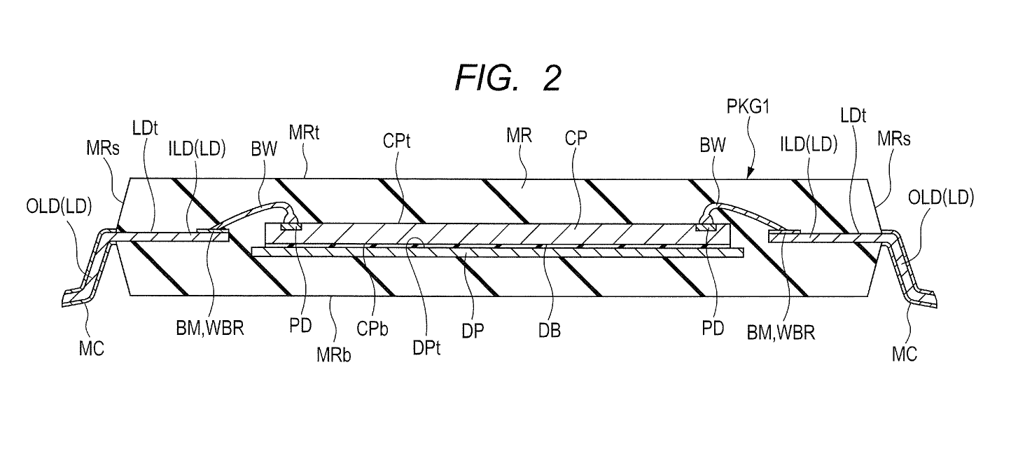

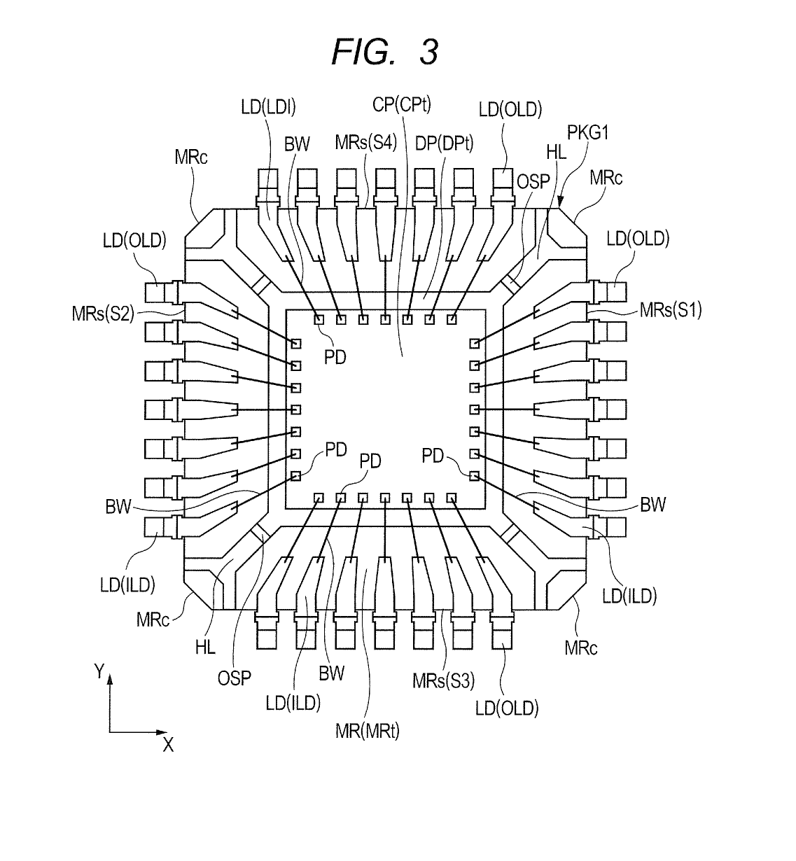

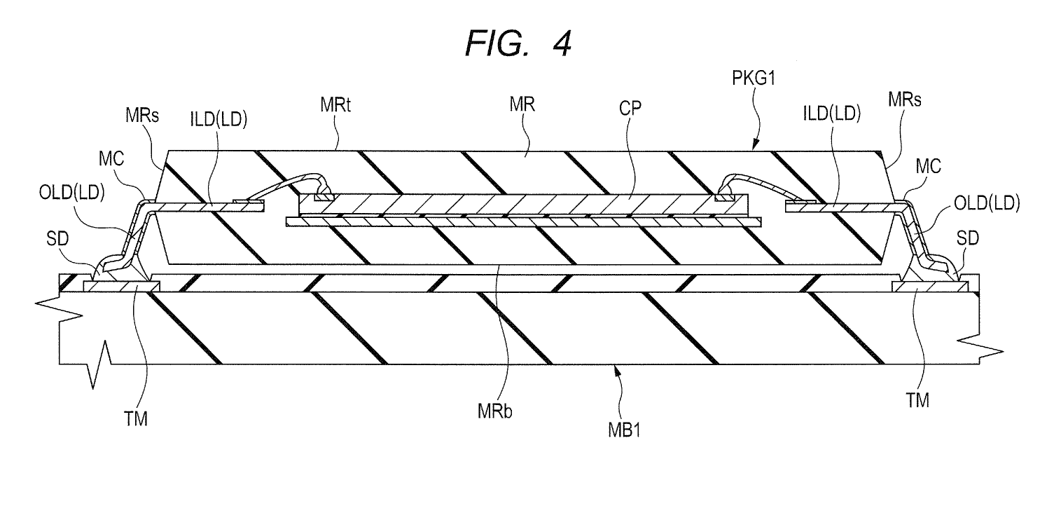

First, the general structure of a semiconductor device PKG1 according to this embodiment will be described referring FIGS. 1 to 4. FIG. 1 is a top view of the semiconductor device according to this embodiment. FIG. 2 is a sectional view taken along the line A-A of FIG. 1. FIG. 3 is a transparent plan view showing the internal structure of the semiconductor device shown in FIG. 1 as seen through its sealing member. FIG. 4 is an enlarged sectional view showing the semiconductor device shown in FIG. 2 as mounted on a mounting board.

As shown in FIGS. 1 to 3, the semiconductor device PKG1 includes a semiconductor chip CP (FIGS. 2 and 3), a plurality of leads LD as external terminals disposed around the semiconductor chip CP, and a plurality of wires BW (FIGS. 2 and 3) as conductive members for coupling the semiconductor chip CP and the leads LD electrically. The semiconductor chip CP and the wires BW are sealed by a sealing member (resin) MR. The inner lead parts ILD (FIGS. 2 and 3) of the leads LD are sealed by the sealing member MR and the outer lead parts OLD of the leads LD are exposed from the sealing member MR.

As shown in FIG. 1, the planar shape of the sealing member MR of the semiconductor device PKG1 is quadrangular. The sealing member MR has an upper surface MRt, a lower surface (back, surface to face the mounting board) MRb (FIG. 2) opposite to the upper surface MRt, and several (four) side surfaces MRs between the upper surface MRt and lower surface MRb.

In plan view, the sealing member MR has aside (main side) S1 extending in the Y direction, a side (main side) S2 opposite to the side S1, a side (main side) S3 extending in the X direction across (perpendicular to) the Y direction, and a side (main side) S4 opposite to the side S3. The four side surfaces MRs of the sealing member MR are disposed along the four sides of the sealing member MR. In the example shown in FIG. 1, the corners MRc where sides of the sealing member MR cross are chamfered.

Here, the corners MRc of the sealing member MR each include an area around the point of intersection of any two sides (two main sides) among the four sides (four main sides) of the sealing member MR. More specifically, as shown in FIGS. 1 and 3, each corner MRc of the sealing member MR is chamfered (in the example shown in FIG. 1, it is chamfered by tapering, but it maybe round-chamfered), so the point of intersection of main sides is located outside the corresponding corner MRc of the sealing member MR. However, since the chamfered portions are far smaller than the main sides in length, an explanation is given here, assuming the center of each chamfered portion as a corner of the sealing member MR. In other words, if an area where any two sides (two mains sides) among the four sides (four main sides) of the sealing member MR cross is chamfered, the chamfered portion is assumed as a corner MRc, and if the area is not chamfered, the point of intersection of the two (main) sides corresponds to a corner MRc. In the description below, the corners MRc of the sealing member MR should be interpreted as mentioned above unless otherwise stated expressly.

In the semiconductor device PKG1, a plurality of leads LD are disposed along each side (each main side) of the sealing member MR with a quadrangular planar shape. The leads LD are each made of a metal material; in this embodiment, they are, for example, copper (Cu)-based metal members.

The outer lead parts OLD of the leads LD protrude from the side surfaces MRs of the sealing member MR towards the outside of the sealing member MR. The exposed surfaces of the outer lead parts OLD of the leads LD have a metal coating (external coating film) MC formed, for example, on the surface of a copper-based base material. The metal coating MC, which is made of a metal material (for example, solder) with higher wettability to solder than the base material (copper), is a metal coating which covers the base material (copper). The formation of the metal coating MC of solder, etc. on each of the outer lead parts OLD of the leads LD as external terminals of the semiconductor device PKG1 improves the wettability of solder members SD as conductive bonding members used to mount the semiconductor device PKG1 on a mounting board MB1 as shown in FIG. 4. This increases the area of contact between the leads LD and the solder members SD, thereby improving the strength of bonding between the leads LD and the terminals TM of the mounting board MB1.

FIG. 2 shows an example that a metal coating MC as a solder film is formed on the exposed surface of the outer lead part OLD of a lead LD by a coating technique. However, various other types of metal coating MC maybe adopted. For example, the metal coating MC may be a laminated film which includes a nickel (Ni)-based metal film and a palladium (Pd)-based metal film. Alternatively it may be a gold (Au)-based metal film overlying a palladium (Pd)-based metal film surface. If the metal coating MC is made of a material other than solder, the metal coating MC may be formed so as to cover the inner lead parts ILD and outer lead parts OLD of the leads LD.

As shown in FIGS. 2 and 3, the semiconductor chip CP is encapsulated by the sealing member MR. As shown in FIG. 3, the semiconductor chip CP is quadrangular in plan view and on the surface CPt, a plurality of pads (bonding pads) PD are disposed along each of the four sides as the outer edges of the surface CPt. The semiconductor chip CP (specifically, the semiconductor substrate) is made of, for example, silicon (Si). A plurality of semiconductor elements (circuit elements) are formed on the main surface of the semiconductor chip CP (specifically, the semiconductor element formation region of the upper surface of the semiconductor substrate of the semiconductor chip CP), though not shown. The pads PD are electrically coupled to the semiconductor elements through wirings (not shown) formed in wiring layers inside the semiconductor chip CP (specifically, between the surface CPt and the semiconductor element formation region (not shown)). In short, the pads PD are electrically coupled to the circuit formed in the semiconductor chip CP.

An insulating film is formed on the surface CPt of the semiconductor chip CP to cover the substrate of the semiconductor chip CP and the wirings, and the surface of each of the pads PD is exposed from the insulating film in an opening made in the insulating film. The pads PD are made of metal and in this embodiment, they are made of, for example, aluminum (Al).

For example, a plurality of leads LD are disposed around the semiconductor chip CP (namely, around a die pad DP). The pads (bonding pads) PD exposed on the surface CPt of the semiconductor chip CP are electrically coupled to the inner lead parts ILD of the leads LD located inside the sealing member MR through a plurality of wires (conductive members) BW, respectively. The wires BW are made of, for example, gold (Au) or copper (Cu) and a portion (for example, one end) of each wire BW is bonded to a pad PD and another portion (for example, the other end) is bonded to the bonding part WBR (FIG. 2) of an inner lead part ILD. A metal coating (coating film, coating metal film) BM (FIG. 2) is formed on the surface of the bonding part WBR of the inner lead part ILD. The metal coating BM is made of, for example, a material containing silver (Ag), gold, or palladium as a main component (for example, a lamination having a thin metal film over a palladium film). The formation of the metal coating BM of a material containing silver (Ag), gold, or palladium as a main component on the surface of the bonding part WBR of the inner lead part ILD increases the strength of bonding with the gold wire BW.

The semiconductor chip CP is mounted over the die pad DP as a chip mounting area. In the example shown in FIG. 3, the upper surface (chip mounting surface) DPt of the die pad DP is a quadrangle whose plane area is larger than the surface area of the semiconductor chip CP. The die pad DP is a supporting member for supporting the semiconductor chip CP and in terms of its shape and size, various modifications to the example shown in FIG. 3 may be adopted. For example, the die pad DP may be circular in planar shape. Also the plane area of the die pad DP maybe smaller than the surface CPt of the semiconductor chip CP.

As shown in FIG. 3, a plurality of hanging leads HL are disposed around the die pad DP. The hanging leads HL are members for holding the die pad DP on a lead frame holder (frame) in the process of manufacturing the semiconductor device PKG1. In the example shown in FIG. 3, four hanging leads HL extend from the corners of the die pad DP toward the corners MRc of the sealing member MR. More specifically, ends of the hanging leads HL are coupled to the corner parts (corners) of the die pad DP. The other ends of the hanging leads HL extend toward the corners MRc of the sealing member MR and bifurcate into two parts near the corners MRc with the bifurcated parts exposed from the sealing member MR on the side surfaces MRs of the sealing member MR. Since the hanging leads HL extend toward the corners MRc of the sealing member MR, they hardly interfere with the leads LD disposed along the sides (main sides) of the sealing member MR.

In this embodiment, the upper surface DPt of the die pad DP is different in height from the upper surface of the inner lead part ILD of each lead LD. In the example shown in FIG. 2, the upper surface DPt of the die pad DP is in a lower position than the upper surface LDt of the inner lead part ILD. Therefore, the hanging leads HL shown in FIG. 3 each have a folded portion or offset (down-set portion in this embodiment) OSP so that the upper surface LDt of the die pad DP is different in height from the inner lead parts ILD of the leads LD (FIG. 2).

The semiconductor chip CP is mounted in the center of the die pad DP. As shown in FIG. 2, the semiconductor chip CP is mounted over the die pad DP through a die bond (adhesive) DB with the back surface CPb facing the upper surface DPt of the die pad DP. In other words, the so-called “face-up” bonding method is adopted in which the surface (back surface) CPb, opposite to the front surface (main surface) CPt holding the pads PD, faces the chip mounting surface (upper surface DPt). The die bond DB is an adhesive used to die-bond the semiconductor chip CP, which is, for example, a resin adhesive of epoxy thermosetting resin containing silver or other metal particles or a metal bonding material such as a solder material.

### <Details of the Leads>

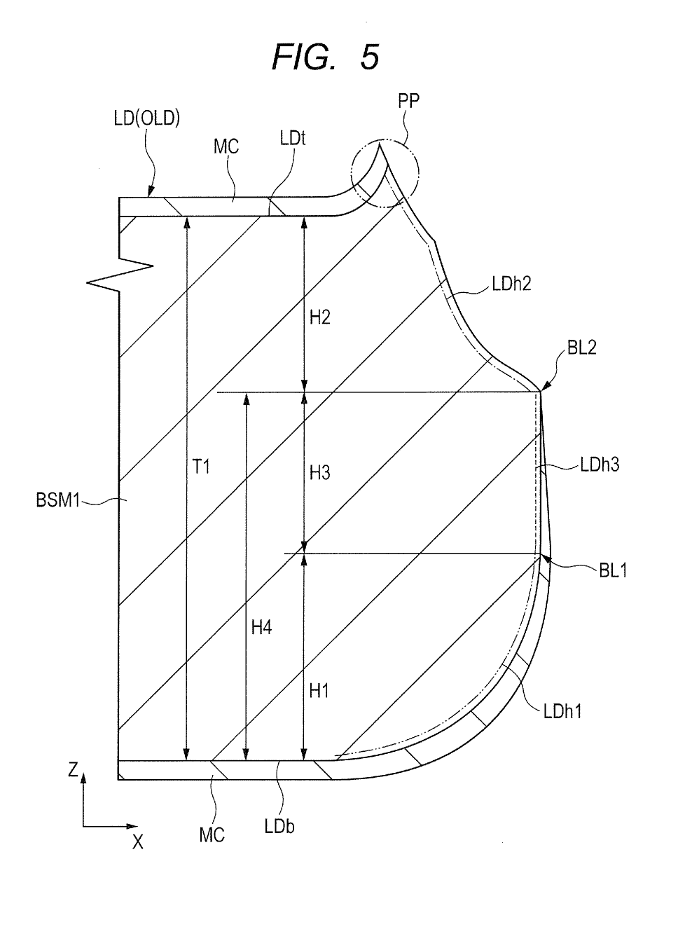

Next, the leads LD of the semiconductor device PKG1 shown in FIGS. 1 to 4 will be explained in detail. In this section, the structure of the tip of the outer lead part of each lead LD will be explained in detail. FIG. 5 is an enlarged sectional view of the tip of the outer lead part of one of the leads shown in FIG. 2. In FIG. 5, chain double-dashed line, chain line, and dotted line are shown adjacent to three different tip end faces LDh1, LDh2, and LDh3 which are formed by different methods, so that the three different tip end faces can be easily identified.

As shown in FIG. 5, the lead LD (specifically, the base material BSM1 of the lead LD) has a lower surface LDb on the lead LD mounting surface side and an upper surface LDt opposite to the lower surface LDb. The upper surface LDt and lower surface LDb are covered by a metal coating MC.

The tip of the lead LD has three different end faces LDh1, LDh2, and LDh3 which are formed by different methods. Specifically, the tip of the lead LD has an end face (side surface) LDh1 continuous with the lower surface LDb, an end face (side surface) LDh2 continuous with the upper surface LDt, and an end face LDh3 continuous with the end surface LDh1 through a border line BL1 and continuous with the end face LDh2 through a border line BL2.

As will be explained in detail later, the end face LDh1 is a deformed surface made by pressing and deforming the lead LD with a punch of the lead cutting mold in the lead cutting step (described later). The end face LDh3 is a shear surface made by pressing and shearing the lead LD by the punch of the mold in the lead cutting step. The end face LDh2 is a fracture surface made by pressing the lead LD and fracturing a portion thereof adjacent to the upper surface LDt by the punch of the mold in the lead cutting step.

The end faces LDh1, LDh2, and LDh3 are all made in the lead cutting step which will be described later and they are made at different times for different reasons. Therefore, the end faces LDh1, LDh2, and LDh3 are covered by the metal coating MC in different ways.

Since the end face LDh1 is made as the lower surface LDb of the lead LD is bended (deformed), the end face LDh1 is covered by the metal coating MC as shown in FIG. 5. The end face LDh2 is a fracture surface with a fracture starting at a crack generated in the lead LD during the latter half of the lead cutting step and as shown in FIG. 5, it is not covered by the metal coating MC and the base material BSM1 is exposed. The end face LDh3 is a surface sheared by the mold, in which in some cases the base material BSM1 is exposed, but in most cases, a portion of the metal coating MC covering the lower surface LDb is dragged by the mold (punch) and rubbed against the end face LDh3. Therefore, as shown in FIG. 5, the metal coating MC covering the end face LDh3 is relatively thick near the border line BL1 and relatively thin near the border line BL2. In some cases, in the vicinity of the border line BL2, the metal coating MC does not adhere and the base material BSM1 of the lead LD is exposed.

Next, the wettability of the solder SD with the semiconductor device PKG1 mounted over the mounting board as shown in FIG. 4 will be discussed. Since the metal coating MC is made of a metal material with higher wettability to the solder SD than the base material BSM1 of the lead LD as mentioned above, in order to improve the wettability of the solder SD it is desirable to make the area of the exposed base material BSM1 small.

Particularly at the tip of the lead LD, the solder SD spreads up in a way to cover the end faces LDh1, LDh2, and LDh3 shown in FIG. 5, so that the area of bonding between the lead LD and the solder SD (FIG. 4) is increased.

Therefore, for the purpose of improving the wettability of the solder SD, it is desirable to decrease the area of the end face LDh2 in which the base material BSM1 is exposed as shown in FIG. 5. In this embodiment, height H4 from the lower surface LDb of the lead LD to the border line BL2 is larger than height H2 from the border line BL2 to the upper surface LDt. In other words, the height H4 from the lower surface LDb of the lead LD to the border line BL2 is larger than one half of thickness T1 of the lead LD (distance between the upper surface LDt and lower surface LDb). Consequently, the solder SD (FIG. 5) easily spreads up to a height larger than one half of the thickness T1 of the lead LD, leading to higher bonding strength.

Also, for the purpose of ensuring stably high wettability of the solder SD, it is desirable that the thickness of the metal coating MC covering the tip end faces be thick. In this connection, since the metal coating MC on the end face LDh1 is thicker than on the end face LDh3, it is more desirable that the end face LDh1 extend up to a higher position in the thickness direction of the lead LD. In this embodiment, as shown in FIG. 5, height H1 from the lower surface LDb of the lead LD to the border line BL1 is larger than height H3 from the border line BL1 to the border line BL2. In short, the end face LDh1, on which the metal coating MC is thicker, extends up to a high position. The solder SD as shown in FIG. 4 surely spreads up at least to the border line BL1, so according to this embodiment, the wettability of the solder SD is stably high.

FIG. 5 shows a cross section of an lead LD in enlarged form. The semiconductor device PKG1 has a plurality of leads LD as shown in FIG. 1. For the purpose of improving the mounting reliability of the semiconductor device, it is desirable that the tip of each of the leads LD have the structure as described above in reference to FIG. 5. The manufacturing method which enables each of the leads LD to have the tip structure as shown in FIG. 5 will be detailed later.

### <Method for Manufacturing a Semiconductor Device>

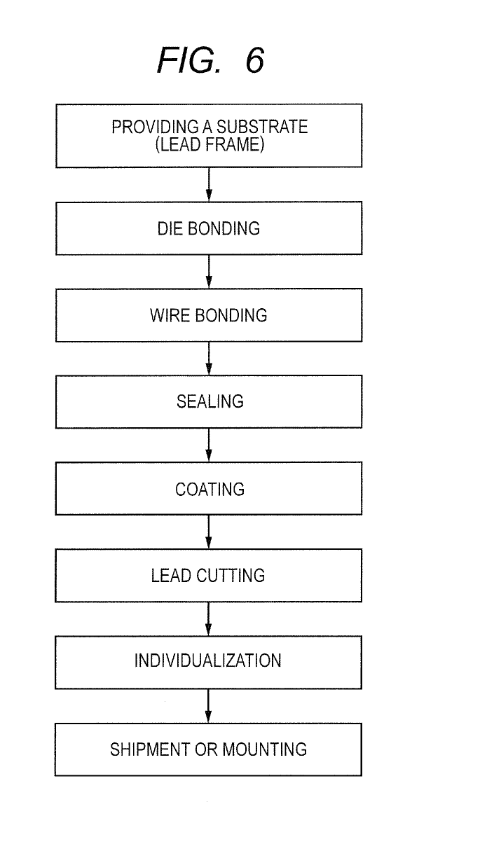

Next, the method for manufacturing the semiconductor device PKG1 described above in reference to FIGS. 1 to 5 will be described referring to the flowchart of FIG. 6. FIG. 6 is a flowchart for explaining the assembly process of the semiconductor device described in reference to FIGS. 1 to 5.

FIG. 6 shows the main steps of the process of manufacturing the semiconductor device PKG1, but the assembly sequence shown in FIG. 6 may be modified in various forms. For example, a marking step to put a product identification mark on the sealing member MR may be added between the sealing step and the coating step, though not shown in FIG. 6. Also, an inspection step may be added, for example, after the individualization step, though FIG. 6 does not show an inspection step.

### <Step of Providing a Substrate>

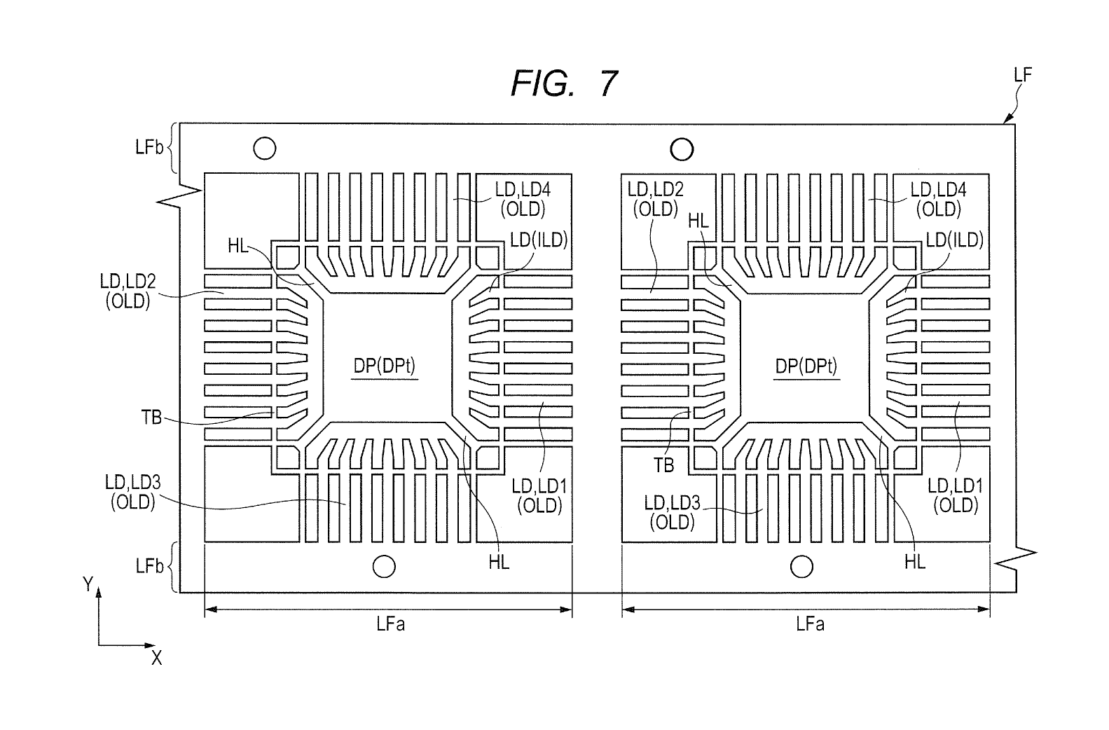

In the step of providing a substrate (FIG. 6), a lead frame LF as shown in FIG. 7 is provided. FIG. 7 is an enlarged plan view of the lead frame provided in the step of providing a substrate (FIG. 6).

The lead frame LF provided in this step includes a plurality of device formation areas LFa inside a frame part LFb. The lead frame LF is made of metal. In this embodiment, it is made of a copper (Cu)-based metal.

In this embodiment, the process is explained by taking, as an example, a case that as shown in FIG. 6, after the sealing step, the coating step is carried out to form a metal coating MC on the outer lead part OLD as shown in FIG. 2. Alternatively, in the step of providing a substrate, the surface of a copper-based substrate may be previously covered by a metal coating MC. If that is the case, the entire exposed surface of the lead frame LF is covered by the metal coating MC.

As shown in FIG. 7, a die pad DP as a chip mounting area is formed in the center of each device formation area LFa. A plurality of hanging leads HL are coupled to each die pad DP and they extend toward the corners of the device formation area LFa. The die pad DP is supported by the frame part LFb of the lead frame LF through the hanging leads HL.

A plurality of leads LD are formed between hanging leads HL around the die pad DP. The leads LD are coupled to the frame part LFb. In this embodiment, the leads LD are located around the die pad DP and extend in the four directions. Specifically, the leads LD include a plurality of leads LD1 and LD2 extending in the X direction, and a plurality of leads LD3 and LD4 extending in the Y direction perpendicular to the X direction. The leads LD1 and the leads LD2 are opposite to each other with the die pad DP between them. The leads LD3 and the leads LD4 are opposite to each other with the die pad DP between them.

The leads LD are mutually coupled by a tie bar TB. The tie bar TB has not only the function as a coupling member for coupling the leads LD but also the function as a dam member for suppressing resin leakage in the sealing step (FIG. 6).

### <Die Bonding Step>

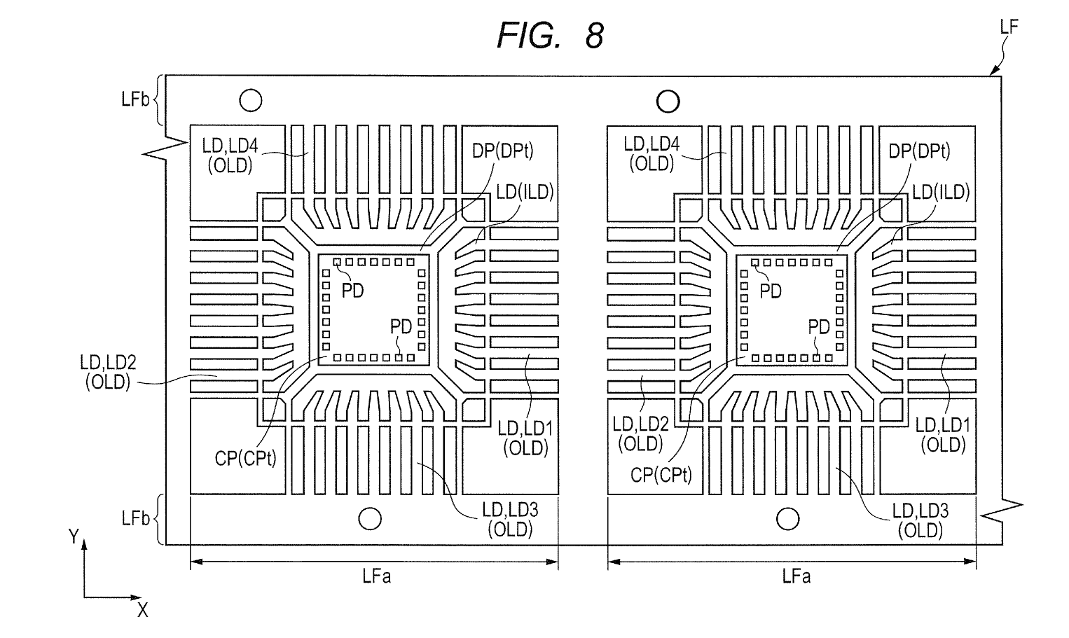

Next, in the die bonding step (FIG. 6) (step of mounting a semiconductor chip), a semiconductor chip CP is mounted over the die pad DP as shown in FIG. 8. FIG. 8 is an enlarged plan view showing the semiconductor chip mounted over the die pad of the lead frame shown in FIG. 7.

As described above in reference to FIG. 2, the semiconductor chip CP has a front surface CPt with a plurality of pads PD formed thereon and a back surface CPb opposite to the front surface CPt. In this step, the semiconductor chip CP and the die pad DP are bonded to each other through a die bond DB as an adhesive of thermosetting resin such as epoxy resin (FIG. 2). In the example shown in FIG. 8, the semiconductor chip CP is mounted so that the upper surface DPt of the die pad DP is partially covered by the semiconductor chip CP in plan view.

As described above in reference to FIG. 2, in this embodiment, the semiconductor chip CP is mounted over the die pad DP by the so-called face-up method in which the back surface CPb faces the upper surface DPt as the chip mounting surface of the die pad DP.

### <Wire Bonding Step>

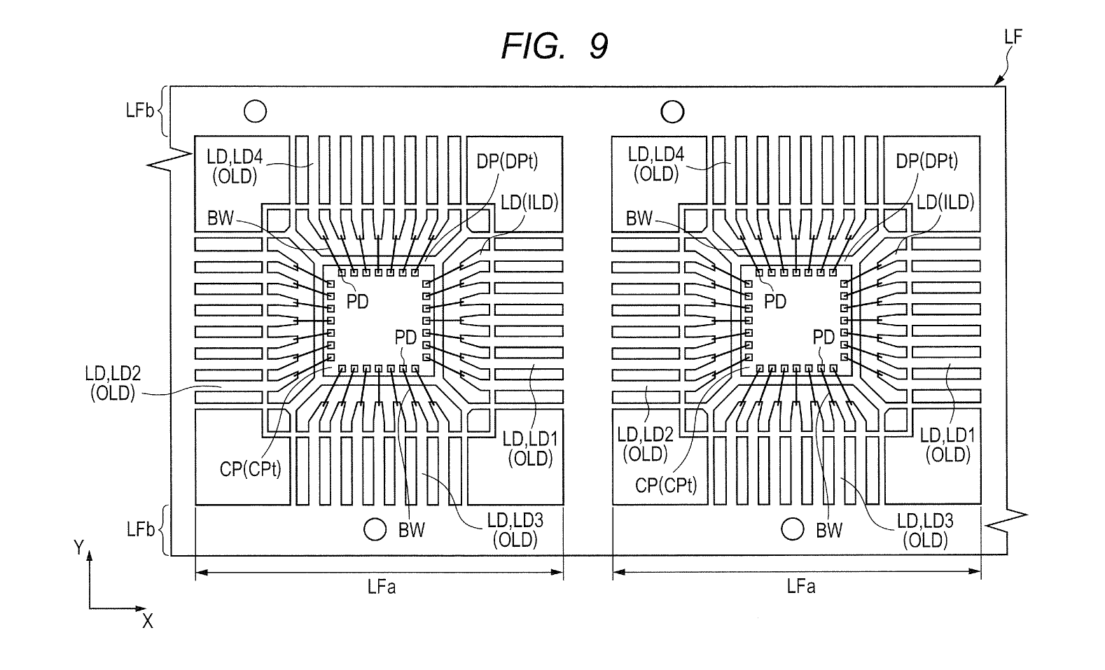

Next, in the wire bonding step (FIG. 6), as shown in FIG. 9, the pads PD formed on the front surface CPt of the semiconductor chip CP and the leads LD formed around the semiconductor chip CP are electrically coupled through a plurality of wires (conductive members) BW, respectively. FIG. 9 is an enlarged plan view showing that the semiconductor chip CP and the leads shown in FIG. 8 are electrically coupled through the wires.

In this step, using a wire bonding tool (not shown), one end of each wire BW of metal such as gold (Au) or copper (Cu) is bonded to a pad PD of the semiconductor chip CP and the other end of the wire is bonded to the inner lead part ILD of a lead LD. The bonding method may be application of ultrasonic waves to the bonding point to make a metallic bond, or thermal compression, or a combination of ultrasonic waves and thermal compression.

### <Sealing Step>

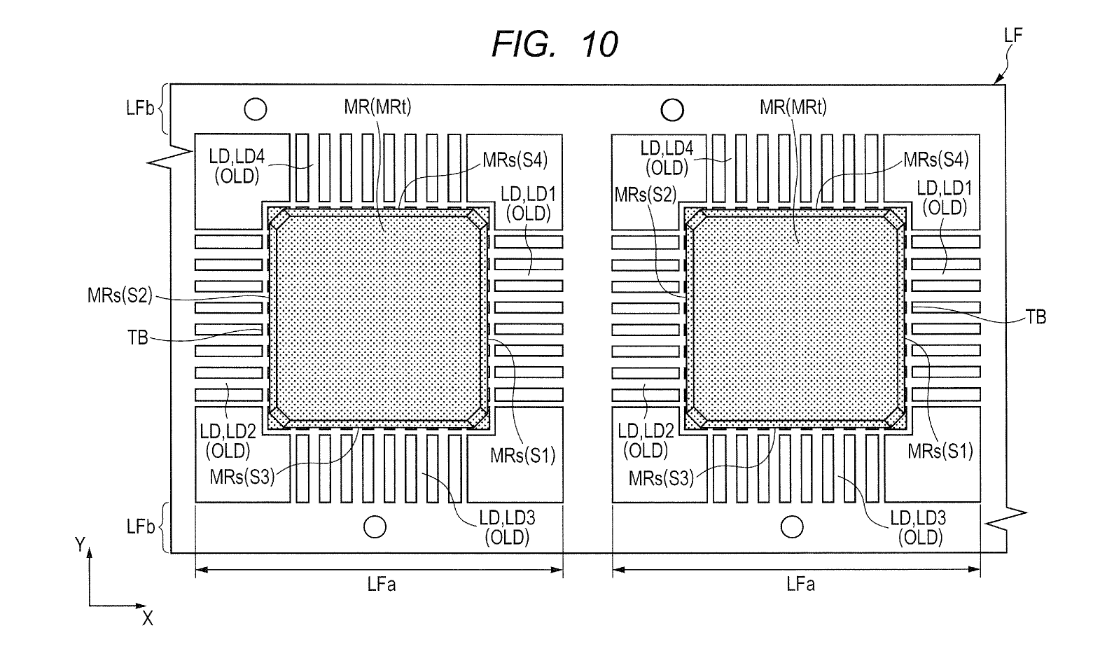

Next, in the sealing step (FIG. 6), the semiconductor chip CP, the wires BW, and the inner lead parts ILD of the leads LD, which are shown in FIG. 9, are sealed by resin to form a sealing member MR as shown in FIG. 10. FIG. 10 is an enlarged plan view showing that a sealing member for sealing a semiconductor chip is formed in each of the device formation areas shown in FIG. 9.

In this step, for example, after the lead frame LD is placed in a mold with cavities (not shown) and resin is supplied to the spaces of the cavities, the resin is hardened to form a sealing member (sealing body) MR. This method for forming the sealing member MR is called the transfer mold method.

In the example shown in FIG. 10, a cavity of the mold is placed in an area surrounded by the tie bar TB of each device formation area LFa. Therefore, as shown in FIG. 10, the main body of the sealing member MR is formed in the area surrounded by the tie bar TB of each device formation area LFa. The tie bar TB blocks the resin leaked from the cavity from flowing. Thus, the outer lead parts OLD of the leads LD are exposed from the sealing member MR.

The outer lead parts OLD of the leads LD1 extending in the X direction, among the leads LD, protrude from the sealing member MR on side S1 corresponding to side MRs of the sealing member MR. The outer lead parts OLD of the leads LD2 extending in the X direction, among the leads LD, protrude from the sealing member MR on side S2 corresponding to side MRs of the sealing member MR. The outer lead parts OLD of the leads LD3 extending in the Y direction, among the leads LD, protrude from the sealing member MR on side S3 corresponding to side MRs of the sealing member MR. The outer lead parts OLD of the leads LD4 extending in the Y direction perpendicular to the X direction, among the leads LD, protrude from the sealing member MR on side S4 corresponding to side MRs of the sealing member MR.

### <Coating Step>

Next, in the coating step (FIG. 6), a metal coating MC (FIG. 2) is formed on the exposed surface of each of the leads LD shown in FIG. 10 by a coating technique. As illustrated in FIG. 4, the metal coating MC formed in this step is intended to ensure that when mounting the semiconductor device PKG1 over the mounting board MB1, the solder SD for electrically coupling the leads LD to terminals TM of the mounting board MB1 respectively easily gets wet and spreads on the leads LD.

In this step, it is desirable that a solder metal coating MC be formed on the exposed surface of each lead LD. As the method for forming a metal coating MC, the electroplating technique may be used in which metal ions are deposited on the exposed surface of the lead LD. The electroplating technique is desirable in the sense that the quality of the metal coating MC can be easily controlled by changing the current to form the metal coating MC. The electrolytic plating technique is desirable in the sense that the time required to form the metal coating MC can be shortened.

### <Lead Cutting Step>

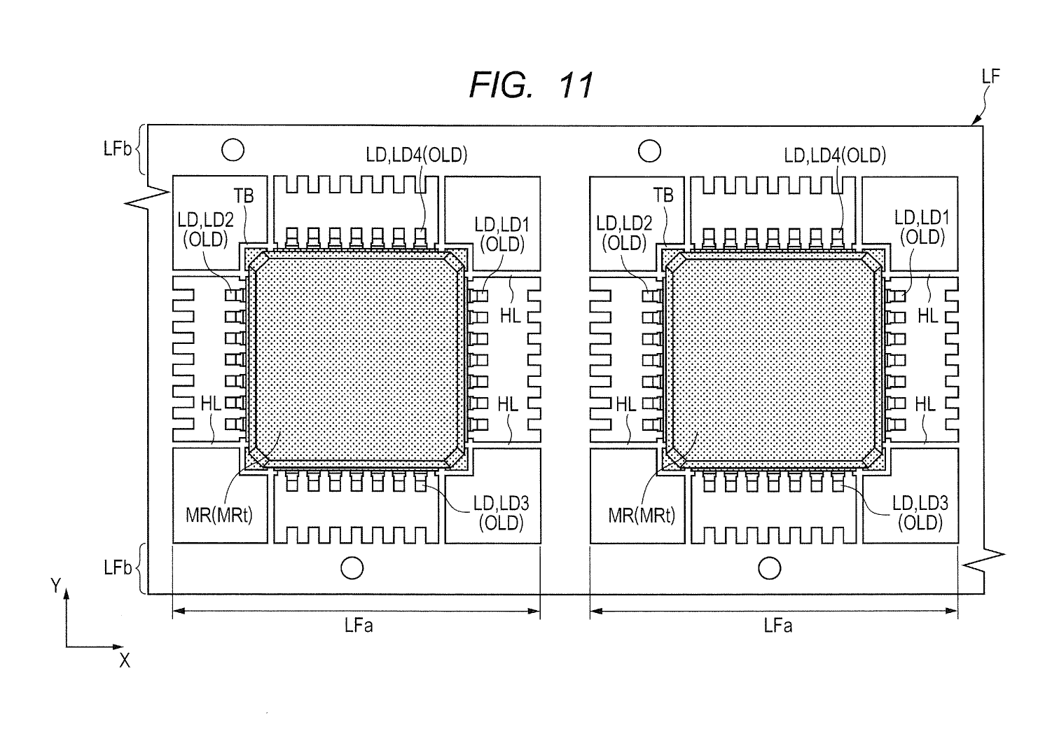

Next, in the lead cutting step (FIG. 6), as shown in FIG. 11, the outer lead parts OLD of the leads LD are cut to separate the leads LD from the lead frame LF. In this embodiment, after cutting the leads LD, the leads LD are reshaped by folding as shown in FIG. 2. FIG. 11 is an enlarged plan view showing that after forming the metal coatings on the exposed surfaces of the leads shown in FIG. 10 and cutting the leads, the leads are reshaped.

In this step, the tie bar TB which interconnects the leads LD is cut. Also, the leads LD are separated from the frame part LFb. As a consequence, the leads LD are each an independent member. After separation of the leads LD from the frame part LFb, the sealing member MR and the leads LD are supported by the frame part LFb through the hanging leads HL.

In the explanation given above, it is assumed that the tie bar TB is cut after the coating step. Alternatively, the tie bar TB may be cut before carrying out the coating step and separating the leads LD from the frame part LFb. If this sequence is adopted, the metal coatings MC also cover the cut faces of the tie bar TB, thereby preventing the cut faces of the tie bar TB from getting discolored due to oxidation. In addition, since the coating step is carried out before the leads LD are separated from the frame part LFb, deformation of the leads LD by the coating liquid is less likely to occur.

The leads LD and the tie bar TB are cut by press work using a cutting mold which will be described later. The cut leads LD are reshaped, for example, into the shape shown in FIG. 2, for example, by bending the outer lead parts OLD of the leads LD by press work using a forming die (not shown).

Details of the lead cutting step will be described later.

### <Individualization Step>

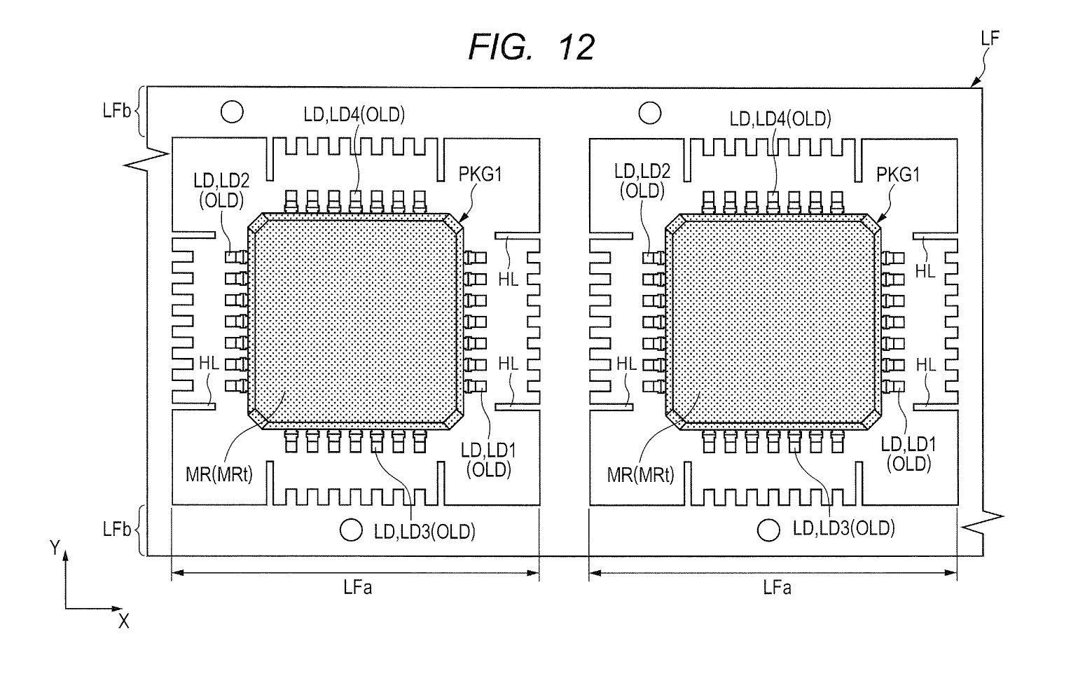

Next, in the individualization step (FIG. 6), as shown in FIG. 12, the hanging leads HL are cut so as to separate the semiconductor package in each of the device formation areas LFa. FIG. 12 is an enlarged plan view showing that the hanging leads HL shown in FIG. 11 are cut and the semiconductor device in each device formation area becomes an individual semiconductor device.

In this step, the hanging leads HL and the resin remaining in the corners of the sealing member MR are cut to obtain a semiconductor device PKG1 as a semiconductor package (more specifically, an inspection object before the inspection step). Cutting may be done, for example, by press work using a cutting mold (not shown) in the same way as in the above step of reshaping leads.

After this step, necessary inspections and tests including an appearance test and an electrical test are conducted. A package which has passed the inspections and tests is a finished semiconductor device PKG1 as shown in FIGS. 1 to 4. The semiconductor device PKG1 is shipped or mounted over the mounting board MB1 shown in FIG. 4.

### <Details of the Lead Cutting Step>

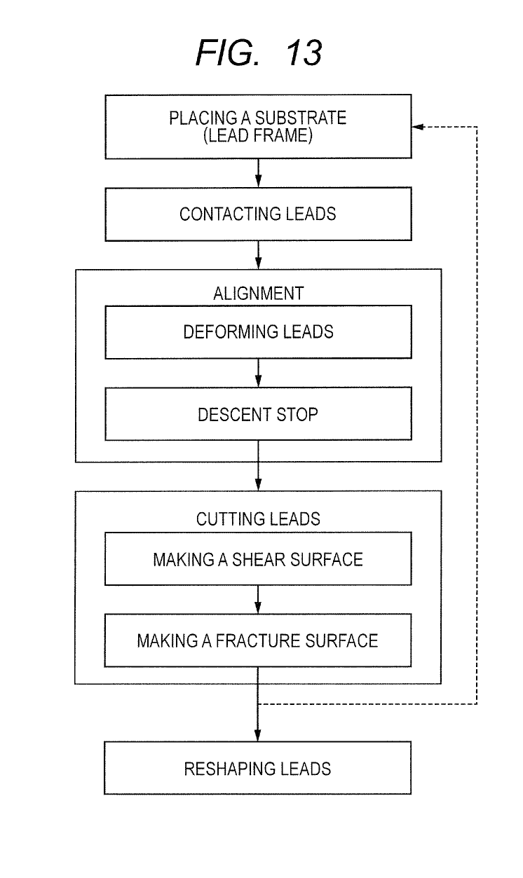

Next, the lead cutting step (FIG. 6) will be explained in detail. FIG. 13 is a flowchart showing details of the lead cutting step shown in FIG. 6.

As described above, for the purpose of improving the wettability of the leads LD shown in FIG. 4 to the solder SD, it is desirable to decrease the area of the tip end face LDh2 where the base material BSM1 is exposed as shown in FIG. 5. In this embodiment, the height H4 from the lower surface LDb of the lead LD to the border line BL2 is larger than the height H2 from the border line BL2 to the upper surface LDt, so the wettability of the lead LD to the solder SD is improved.

Also, for the purpose of ensuring stably high wettability of the solder SD, it is desirable that the thickness of the metal coating MC covering the tip end faces be thick. In this embodiment, as shown in FIG. 5, the height H1 from the lower surface LDb of the lead LD to the border line BL1 is larger than the height H3 from the border line BL1 to the border line BL2, so the wettability of the solder SD is stably high.

As described above, at the tip of the lead LD, the base material of the lead LD is covered by the metal coating MC of a metal material with high wettability to the solder SD so that the wettability of the solder SD to the tip is improved. Consequently, the mounting strength of the semiconductor device PKG1 is increased and the mounting reliability of the semiconductor device PKG1 is enhanced.

For a product having a plurality of leads LD like the semiconductor device PKG1, when each of the leads is formed to have the abovementioned tip configuration, the overall mounting reliability of the product (semiconductor device PKG1) is enhanced.

On the other hand, in order to improve the efficiency in manufacturing the semiconductor device PKG1, it is desirable to cut the leads LD simultaneously. When the number of leads LD in one semiconductor device PKG1 increases, in order to improve the manufacturing efficiency, it is important to decrease the number of cutting times.

For this reason, the present inventors explored a technique to improve the accuracy in processing leads at the time of cutting the leads simultaneously and enhance the mounting reliability of the semiconductor device. First, the inventors considered improving the accuracy in assembling the cutting molds used in the lead cutting step and decreasing the clearance distance between the molds for press work. The inventors thought that if the mold assembling accuracy is improved, the leads to be cut simultaneously can be cut under the same conditions.

However, the inventors realized that the following problem cannot be solved simply by improving the cutting mold assembling accuracy.

In press work which uses molds, while one mold (called “die”) is supporting leads LD, the other mold (called “punch”) is pressed against the leads LD. The punch and the die are located with a small clearance distance of several to ten-odd microns between them and as the punch is pushed until it faces the die, the leads are pinched and cut by the punch and die. If the punch and the die should contact each other, the molds might be damaged, so in order to make the clearance distance between the punch and die small, it maybe necessary to decrease the amount of shift of the punch in the sliding axis X-Y plane directions (range of movement in the direction in which the leads LD extends) at the time of pushing the punch.

However, it was found that if the clearance distance between the punch and die and the amount of shift of the punch in the sliding axis X-Y plane directions are each decreased to 2 to 3 μm or so, the influence of the ambient temperature in cutting work must be considered. This means that the ambient temperature in cutting work may cause thermal expansion of the metal of the molds and change the clearance distance. If the clearance distance is 5 μm or more, contact between the die and punch does not occur even with thermal expansion of the molds. However, as described above, if the clearance distance between the punch and die is small, contact between the punch and die may occur depending on the degree of thermal expansion.

With this in mind, the present inventors made further research and found that when cutting leads LD by press work, the cutting position can be adjusted by increasing the margin for the guide to determine the range of movement of the punch in the X direction and using the reactive forces of the pressed leads LD. Next, how a lead LD is cut will be explained in detail step by step.

In order to simplify the explanation about how alignment is performed when cutting leads LD in this embodiment, it is assumed that among the leads LD shown in FIG. 10, the leads LD1 and LD2 extending in the X direction are first cut simultaneously and then the leads LD3 and LD4 extending in the Y direction are cut simultaneously.

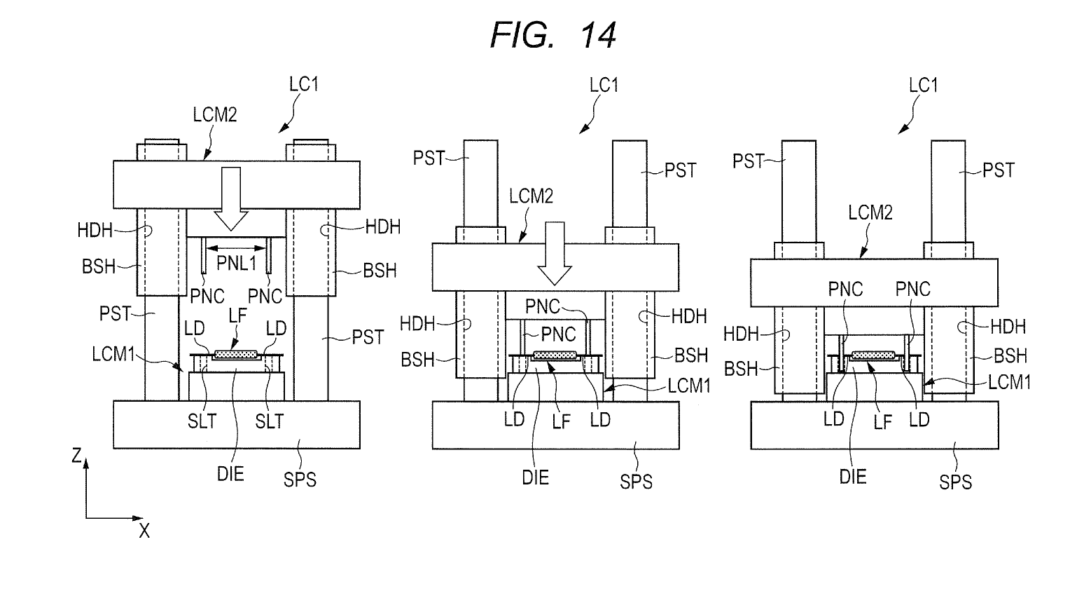

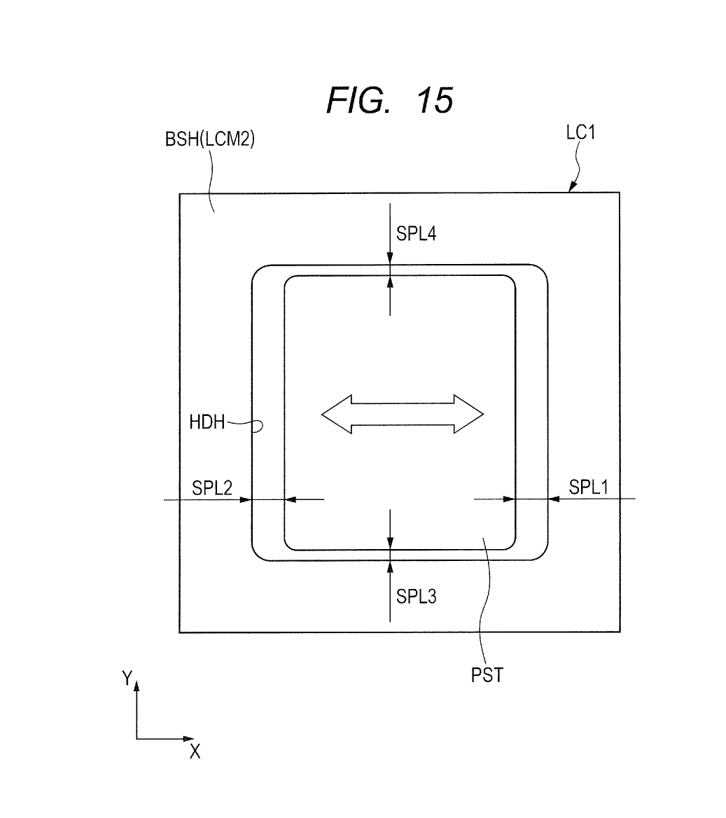

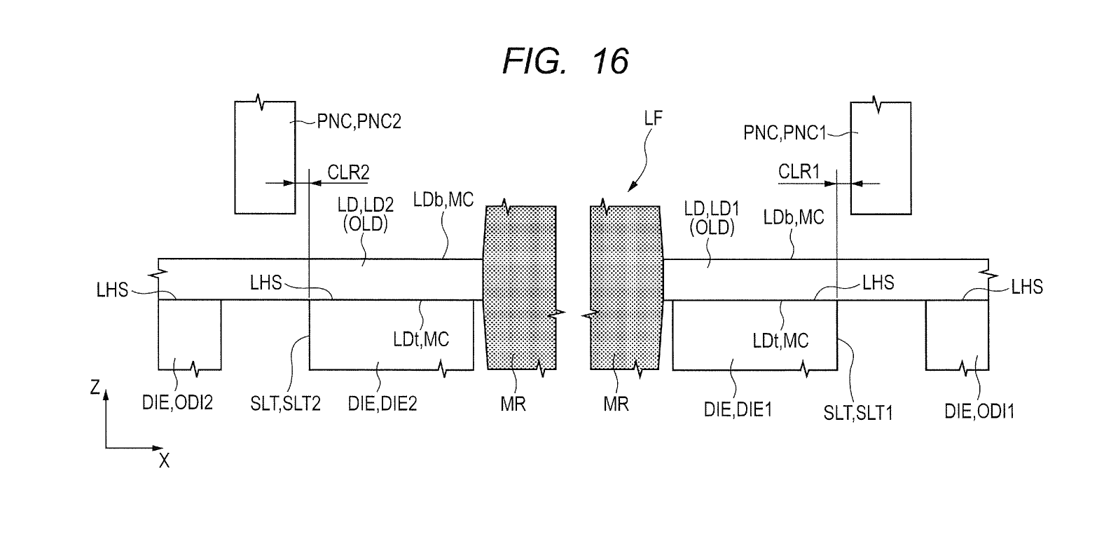

FIG. 14 is a view for explaining the general structure of a lead cutter for cutting leads as used in this embodiment and how its moving parts work. FIG. 15 is a plan view showing the planar positional relation between the post and bush shown in FIG. 14. FIG. 16 is an enlarged side view showing a lead frame placed on the lead cutter in the step of placing a substrate (FIG. 13).

In order to illustrate how an upper mold LCM2 slides, FIG. 14 includes side views of different stages of sliding movement of the upper mold LCM2. In FIG. 15, in order to show clearly the gap between the post PST inserted in the through hole HDH of the bush BSH and the sidewall of the through hole HDH, the gap and its vicinity are shown in enlarged form with a scale ratio which is different from the scale ratio for the rest. In FIG. 16, in order to show both a lead LD1 and its vicinity and a lead LD2 and its vicinity in the figure, the sealing member MR is partially omitted. Also, in FIG. 16, in order to show clearly the difference between clearance distance CLR1 and clearance distance CLR2, the scale ratio for the clearance between the punch PNC and die DIE is different from the scale ratio for the rest and the clearance is shown in enlarged form. Similarly, in the enlarged sectional views illustrating details of the lead cutting step, which will be referred to next, the sealing member MR is partially omitted and the clearance between the punch PNC and die DIE is shown in enlarged form.

As shown in FIG. 14, in this embodiment, the lead cutter LC1 which cuts a plurality of leads LD simultaneously includes a lower mold (first mold) LCM1 for supporting the leads LD and an upper mold (second mold) LCM2 supported in a way to be able to move toward the lower mold LCM1.

The lower mold LCM1 has dies for supporting leads LD in the lead frame LF and is fixed on the support SPS of the lead cutter LC1. The upper mold LCM2 has a plurality of punches PNC as blades for cutting leads LD simultaneously.

As schematically illustrated with bold arrows in FIG. 14, the upper mold LCM2 is located in the lead cutter LC1 in a way to be able to slide in the thickness direction of the lead frame LF (Z direction in FIG. 14). In the example shown in FIG. 14, a plurality of posts (guide rails) PST for controlling the direction of movement of the upper mold LCM2 are fixed on the support SPS of the lead cutter LC1. The posts PST each have a shaft (sliding axis) which extends in the height direction of the lead cutter LC1 (namely the Z direction, the thickness direction of the lead frame LF). The upper mold LCM2 has bushes (rail holders) BSH which hold the posts PST and slide in the axis direction of the posts PST (direction of extension, Z direction). The bushes BSH each have a through hole HDH penetrating the base material in the Z direction, which is the same as the thickness direction of the lead frame LF, and each post PST is inserted in a through hole HDH. The upper mold LCM2 has a plurality of bushes BSH (two bushes shown in FIG. 14), the number of which is equal to the number of posts PST. The posts PST are inserted in the through holes HDH of the bushes BSH respectively so that the direction of movement of the upper mold LCM2 is controlled in the direction in which the posts PST extend, namely the Z direction, which is the same as the thickness direction of the lead frame LF.

As shown in FIG. 15, the external size of the post PST is smaller than the opening size of the through hole HDH of the bush BSH in plan view. For this reason, there are gaps between the inner sidewall of the through hole HDH of the bush BSH and the periphery of the post PST. More specifically, there are gap distances SPL1 and SPL2 in the X direction in which the lead LD1 and lead LD2 extend as shown in FIG. 16, and gap distances SPL3 and SPL4 in the Y direction perpendicular to the X direction.

The research by the present inventors has revealed that it is desirable to increase the amount of shift of the punch PNC in its sliding axis X direction as shown in FIG. 14 by increasing the sum of the gap distances SPL1 and SPL2. In other words, it is desirable to increase the margin for the range of movement of the punch PNC in the X direction. In this embodiment, among the leads LD shown in FIG. 10, the leads LD1 and LD2 extending in the X direction are cut before the leads LD3 and LD4 extending in the Y direction are cut. Therefore, the sum of the gap distances SPL1 and SPL2 in the X direction of FIG. 15 is larger than the sum of the gap distances SPL3 and SPL4.

For example, the sum of the gap distances SPL3 and SPL4 is less than twice the dimensional tolerance (for example, ±3 μm) of distance PNL1 between neighboring punches PNC as shown in FIG. 14. In the Y direction, the gap distances SPL3 and SPL4 only have to allow a lubricant such as oil to be filled between the bush BSH and post PST. Thus, the sum of the gap distances SPL3 and SPL4 is about 6 to 10 μm.

On the other hand, the sum of the gap distances SPL1 and SPL2 shown in FIG. 15 is not less than twice the dimensional tolerance (for example, ±3 μm) of the distance PNL1 between neighboring punches PNC shown in FIG. 14. In the example shown in FIG. 15, the sum of the gap distances SPL1 and SPL2 is 20 μm or more.

When the sum of the gap distances SPL1 and SPL2 in the X direction is large like this, the bush BSH not only slides in the Z direction (FIG. 14) but also easily moves in the X direction as schematically indicated by the bidirectional arrow in FIG. 15. As a consequence, when the upper mold LCM2 (FIG. 14) slides, the punches PNC easily move in the X direction.

As will be detailed later, in a variation of this embodiment, in which the leads LD1, leads LD2, leads LD3, and leads LD4 (FIG. 10) are cut simultaneously, the sum of the gap distances SPL3 and SPL4 may be as large as the sum of the gap distances SPL1 and SPL2. In other words, the sum of the gap distances SPL3 and SPL4 shown in FIG. 15 may be not less than twice the dimensional tolerance (for example, ±3 μm) of the distance PNL1 between neighboring punches PNC shown in FIG. 14. In this case, when the upper mold LCM2 shown in FIG. 14 slides, the punches PNC easily move in any direction on the X-Y plane.

The die DIE of the lower mold LCM1 has a plurality of slits SLT. More specifically, as shown in FIG. 16, the slits SLT are openings in the lead holding surface (supporting surface) LHS of the die DIE and are designed so that when the upper mold LCM2 shown in FIG. 14 moves toward the lower mold LCM1, the punches PNC are inserted into the slits SLT.

For example, the slits SLT form a pattern of grooves penetrating the die DIE in the thickness direction of the die DIE. Alternatively, the slits SLT may form a pattern of grooves not penetrating the die DIE in the thickness direction of the die DIE (namely a pattern of bottomed grooves).

In the lead cutter LC1, while the leads LD in the lead frame LF are supported by the die DIE, the upper mold LCM2 is moved toward the lower mold LCM1 and the punches PNC are inserted into slits SLT. The portions of the leads LD in a position to overlap slits SLT are pinched between the punches PNC and die DIE and sheared.

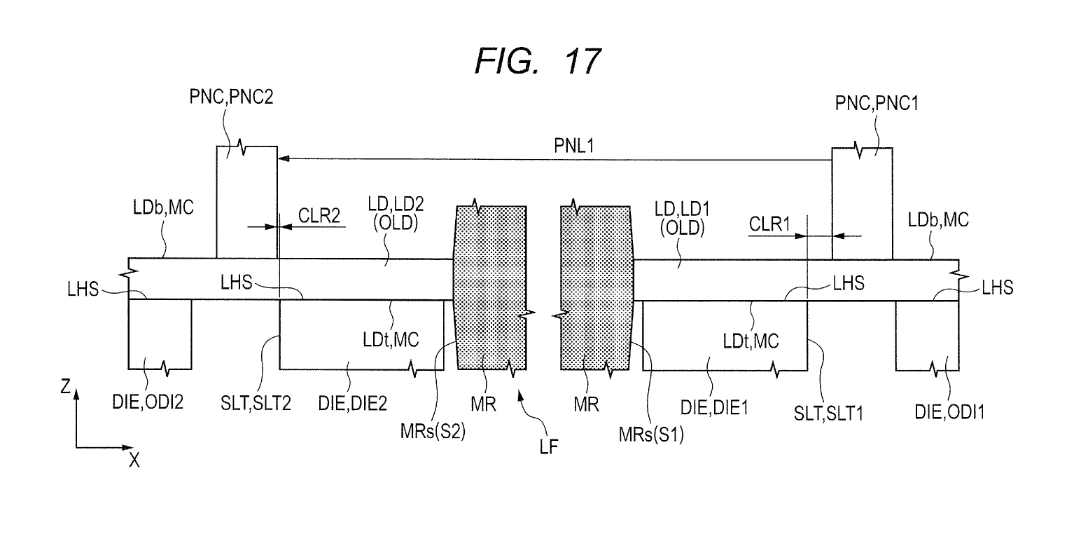

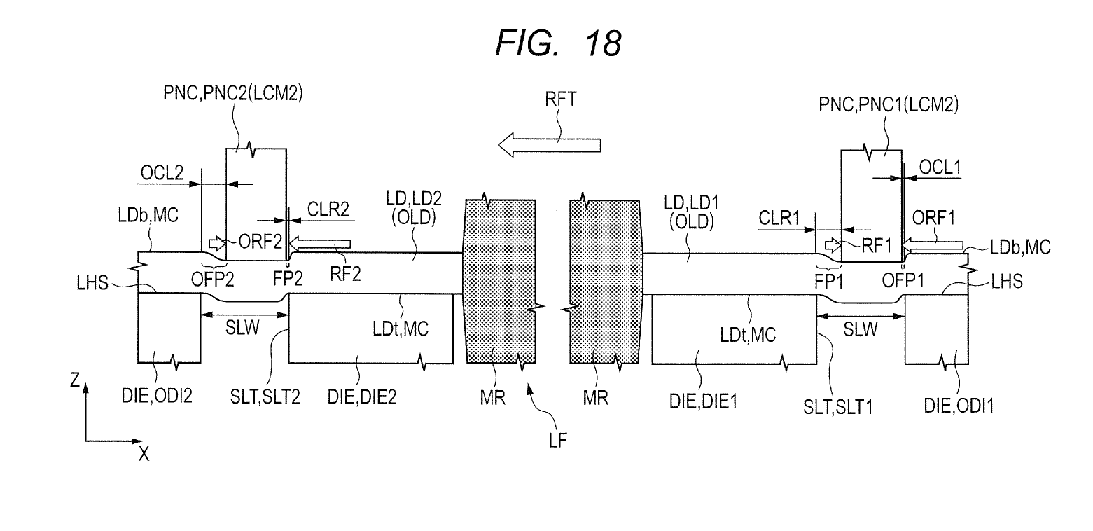

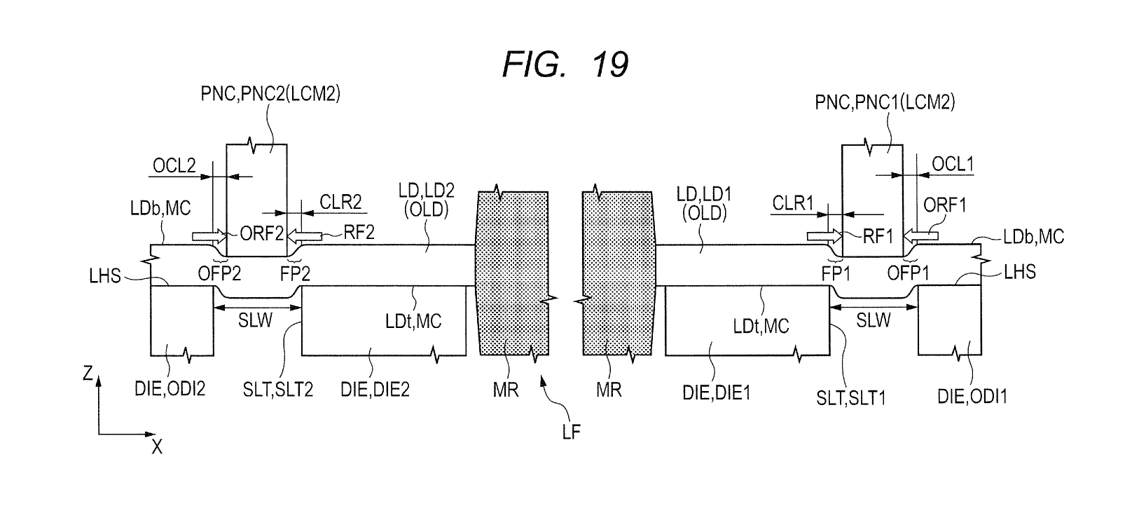

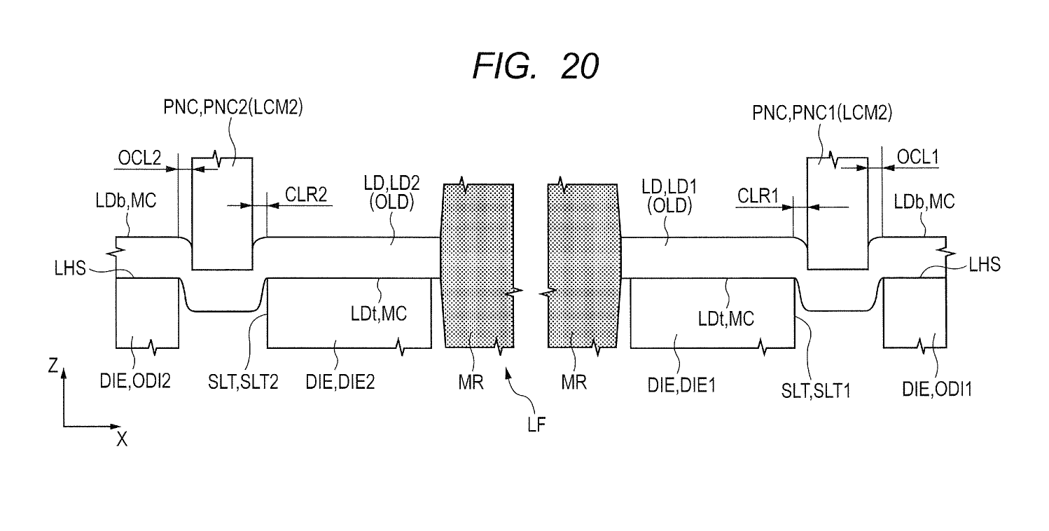

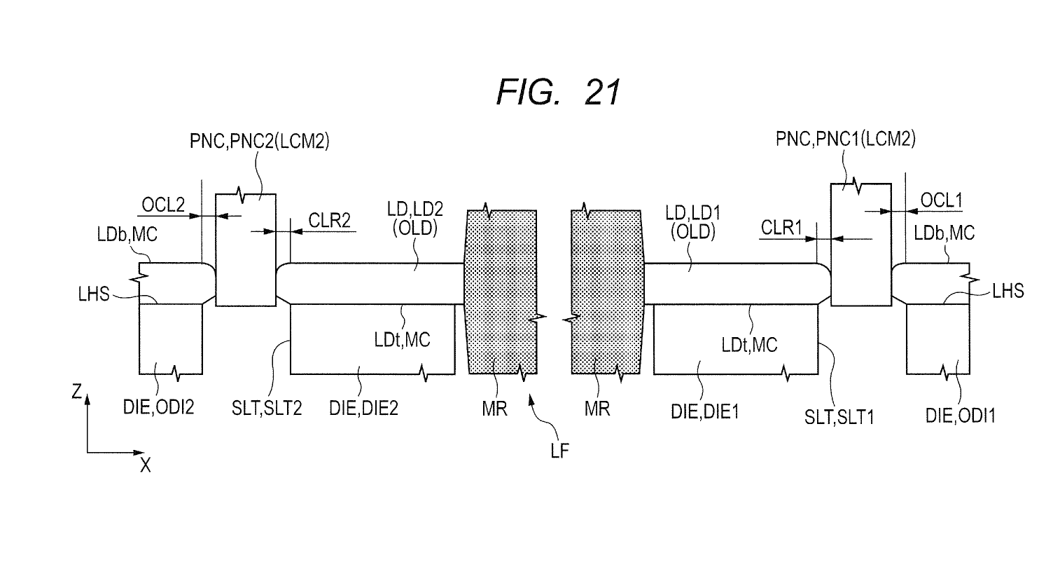

Next, how leads LD are cut simultaneously using the lead cutter LC1 shown in FIG. 14 will be explained in further detail. As shown in FIG. 13, the lead cutting step according to this embodiment includes the following steps: placing a substrate, contacting leads, alignment, cutting leads, and reshaping leads. FIG. 17 is an enlarged side view showing that the punches shown in FIG. 16 are in contact with leads in the step of contacting leads (FIG. 13). FIG. 18 is an enlarged side view showing that in the step of deforming leads (FIG. 13), the leads are partially deformed. FIG. 19 is an enlarged side view showing that in the step of alignment (FIG. 13), clearance distances between punches and dies have been adjusted. FIG. 20 is an enlarged side view showing that in the step of making a shear surface (FIG. 13), the leads are partially sheared. FIG. 21 is an enlarged side view showing that in the step of making a fracture surface (FIG. 13), the leads are cut by fracturing portions of the leads adjacent to their upper surfaces.

First, in the step of placing a substrate, a lead frame LF is placed on the lower mold LCM1 of the lead cutter LC1 as shown in FIG. 14. In this step, the lead frame LF shown in FIG. 10 is turned upside down and placed on the lower mold LCM1. Consequently, the lead holding surface LHS of the die DIE contacts the upper surface LDt of each of the leads LD as shown in FIG. 16. The lower surface LDb of the lead LD does not contact the die DIE.

More specifically, in this embodiment, the lower mold (LCM1) (FIG. 14) includes a die DIE1 for supporting a lead LD1 and a die DIE2 for supporting a lead LD2. In the example shown in FIG. 16, the lead LD1 is also supported by a die ODI1 facing the die DIE1 with a slit SLT1 between them. The lead LD2 is also supported by a die ODI2 facing the die DIE2 with a slit SLT2 between them.

In this step, the upper surface LDt (specifically, the metal coating MC covering the upper surface LDt) of the outer lead part OLD of the lead LD1 is made to contact with the lead holding surface LHS of the die DIE1 and the lead holding surface LHS of the die ODI1. Also, in this step, the upper surface LDt (specifically, the metal coating MC covering the upper surface LDt) of the outer lead part OLD of the lead LD2 is made to contact with the lead holding surface LHS of the die DIE2 and the lead holding surface LHS of the die ODI2.

In this embodiment, since the lead LD to be cut is placed on the die DIE with the lead frame LF upside down, part of the metal coating MC is rubbed against the end face LDh3 as shown in FIG. 5. In addition, when the lead LD is cut by press work as in this embodiment, a protruding part PP as shown in FIG. 5 might be formed at the end opposite to the cutting start point. Therefore, cutting is started from the lower surface LDb of the lead LD, thereby preventing the formation of a protruding part PP on the lower surface LDb.

Next, in the step of contacting leads (FIG. 13), the upper mold LCM2 shown in FIG. 14 is moved closer to the lower mold LCM1 until the punches PNC contact the lower surfaces LDb of the leads LD as shown in FIG. 17. In other words, in this step, after the step of placing a substrate, the upper mold LCM2 (FIG. 14) is moved closer to the lower surface LDb of the lead LD1 and the lower surface LDb of the lead LD2 and made to contact them. At this time, the lower surface LDb of each lead LD is covered by the metal coating MC, so the punch PNC contacts the metal coating covering the lead LD.

In this embodiment, when the upper mold LCM2 slides in the Z direction shown in FIG. 14, the upper mold LCM2 easily moves in the X direction as schematically indicated by the bidirectional arrow in FIG. 15. For this reason, when the leads LD contact the punches PNC in the X direction, clearance distance CLR1 from the punch PNC1 to the die DIE1 and clearance distance CLR2 from the punch PNC2 to the die DIE2 may be different as shown in FIG. 7. In the example shown in FIG. 17, the clearance distance CLR1 is larger than the clearance distance CLR2.

In this step, the range of movement of the upper mold LCM2 (FIG. 15) in the X direction is equivalent to the sum of the gap distances SPL1 and SPL2. Therefore, when the leads LD contact the punches PNC in the X direction, the clearance distance CLR1 may be equal to the clearance distance CLR2.

When leads LD are cut by press work as in this embodiment, the configuration of the tip end of a cut lead LD varies depending on the clearance distance between the punch PNC and the die DIE. Therefore, in order to make the tip of each cut lead LD have the desired configuration as illustrated in FIG. 5, it is desirable to perform alignment so as to equalize the clearance distance CLR1 and the clearance distance CLR2.

For this reason, in this embodiment, the positions of the punches PNC1 and PNC2 and the dies DIE1 and DIE2 are adjusted in the step of alignment (FIG. 13). As mentioned earlier, the distance PNL1 (FIG. 17) between the neighboring punches PNC1 and PNC2 is adjusted accurately, for example, with a tolerance of about ±3 μm and the punches PNC1 and PNC2 are fixed on the upper mold LCM2 (FIG. 14). Thus, in the step of alignment, the entire upper mold LCM2 is moved within the range of the sum of the gap distances SPL1 and SPL2 shown in FIG. 15.

In this step, alignment is performed so as to equalize the clearance distance CLR1 from the punch PNC1 to the die DIE1 and the clearance distance CLR2 from the punch PNC2 to the die DIE2 in the X direction shown in FIG. 17.

Here, “alignment is performed so as to equalize” implies that “alignment is performed so that the clearance distance CLR1 and the clearance distance CLR2 are nearly equal”. In other words, “alignment is performed so as to equalize” means “moving the punches PNC so that the difference between the clearance distance CLR1 and the clearance distance CLR2 is close to 0”. Therefore, the step of alignment does not always imply that alignment is performed until the difference between the clearance distance CLR1 and the clearance distance CLR2 becomes 0.

More specifically, even if the clearance distance CLR1 and the clearance distance CLR2 are slightly different, when the tips of cut leads LD each have the configuration described above in reference to FIG. 5, the clearance distance CLR1 and the clearance distance CLR2 may be considered to be substantially equal.

Here, “substantially equal” includes a case that the difference between the clearance distance CLR1 and the clearance distance CLR2 is smaller than the smaller one of the clearance distance CLR1 and clearance distance CLR2. Also, it is particularly desirable that the difference between the clearance distance CLR1 and the clearance distance CLR2 be within the tolerance (for example, 6 μm) of the distance PNL1 between the punches PNC as shown in FIG. 17. In such a case, the clearance distances CLR1 and CLR2 are here considered to be “substantially equal”.

If, after the punches PNC contact the leads LD, they are moved to increase the difference between the clearance distance CLR1 and the clearance distance CLR2, such movement is not considered as “alignment” performed “so as to equalize” as mentioned above.

Next, how alignment is performed to equalize the clearance distance CLR1 and the clearance distance CLR2 will be concretely explained. As shown in FIG. 13, the step of alignment includes the step of deforming leads. In the step of deforming leads, the upper mold LCM2 (FIG. 14) is moved toward the lower mold LCM1 (FIG. 14) until the leads LD1 and LD2 are partially deformed as shown in FIG. 18.

The leads LD1 and LD2 are each sandwiched between the punch PNC and the die DIE and the degree of their deformation varies depending on the clearance distance between the punch PNC and the die DIE. Specifically, if the clearance distance CLR1 is larger than the clearance distance CLR2 as in the example shown in FIG. 18, the vicinity of the portion FP1 of the lower surface LDb of the lead LD1 between the punch PNC1 and the die DIE1 is deformed at a relatively small inclination angle or gentle angle. On the other hand, the vicinity of the portion FP2 of the lower surface LDb of the lead LD2 between the punch PNC2 and the die DIE2 is deformed at a larger inclination angle or steeper angle than the vicinity of the portion FP1.

If the opening width SLW of the slit SLT1 and SLT2 is constant (if an error is within the tolerance, the opening width is considered as constant), the clearance distance CLR1 and the clearance distance OCL1 as shown in FIG. 18 are inversely proportional to each other. Also, if the opening width SLW is constant, the clearance distance CLR2 and the clearance distance OCL2 as shown in FIG. 18 are inversely proportional to each other. Namely, when the clearance distance CLR1 is larger, the clearance distance CLR2 and the clearance distance OCL1 are smaller. On the other hand, when the clearance distance CLR2 is larger, the clearance distance CLR1 and the clearance distance OCL2 are smaller.

Therefore, in the example shown in FIG. 18, the vicinity of the portion OFP1 of the lower surface LDb of the lead LD1 between the punch PNC1 and the die ODI1 is deformed at a larger inclination angle or steeper angle than the vicinity of the portion FP1. On the other hand, the vicinity of the portion OFP2 of the lower surface LDb of the lead LD2 between the punch PNC2 and the die ODI2 is deformed at a smaller inclination angle or gentler angle than the vicinity of the portion FP2.

When a metal member such as a lead LD is deformed by applying an external force, a reactive force from the metal member is given to a pressing member for applying an external force (punch PNC in this example). In FIG. 18, the X components of the reactive forces generated in the portions FP1, FP2, OFP1, and OFP2 are indicated by arrows and designated as reactive forces RF1, RF2, ORF1, and ORF2, respectively. In addition, in FIG. 18, the lengths of the linear portions of the arrows represent the magnitudes of the reactive forces RF1, RF2, ORF1, and ORF2.

As shown in FIG. 18, the magnitudes of the X components of the reactive forces RF1, RF2, ORF1, and ORF2 are inversely proportional to the clearance distances CLR1, CLR2, OCL1, and OCL2 respectively. In the portions FP2 and OFP1 deformed at a steeper angle, the magnitudes of the reactive forces RF2 and ORF1 are larger than the magnitudes of the reactive forces RF1 and ORF2. The X components of the reactive forces RF1, RF2, ORF1, and ORF2 are summed up and consequently, a reactive force RFT is applied to the upper mold LCM2 with the punches PNC1 and PNC2 fixed, in the direction from the lead LD1 to the lead LD2 as schematically indicated by an arrow (RFT).

Since the punches PNC1 and PNC2 are fixed on the upper mold LCM2 as mentioned above, the punches PNC1 and PNC2 do not move separately, but the entire upper mold LCM2 moves by the reactive force. Consequently, the punches PNC1 and PNC2 move in the direction from the lead LD1 to the lead LD2 as shown in FIG. 18. The direction in which the punches PNC1 and PNC2 move is the same as the direction of movement to decrease the difference between the clearance distances CLR1 and CLR2.

In other words, in this embodiment, the reactive force RFT generated by partially deforming the leads LD is used to perform alignment so as to equalize the clearance distances CLR1 and CLR2. Since this alignment method uses the reactive forces transmitted from the leads LD to the punches PNC, the method will be hereinafter referred to as the self-alignment method.

The above self-alignment method can be achieved by increasing the sum of the gap distances SPL1 and SPL2 as described above in reference to FIG. 15. When the sum of the gap distances SPL1 and SPL2 is large, the range of movement of the upper mold LCM2 in the X direction is wide. Thus, when the reactive force RFT shown in FIG. 18 is applied, the punches PNC1 and PNC2 can move in the direction from the lead LD1 to the lead LD2.

In the step of alignment according to this embodiment, the punches PNC press down the leads LD until the leads LD are partially deformed. However, it is desirable to finish alignment of the punches PNC and the dies DIE before starting cutting (shearing) the leads LD. The reason is that as cutting of the leads LD is started, the punches PNC partially bite into the leads LD and hardly move in the X direction.

For this reason, the alignment step in this embodiment includes the descent stop step to stop the movement of the upper mold LCM1 (downward movement) toward the lower mold LCM1 (in the Z direction) as shown in FIG. 14 temporarily before the leads LD are deformed and cutting of the leads LD is started. In the descent stop step, descent of the upper mold LCM2 in the Z direction is stopped but its movement in the X direction (FIG. 14) is not restricted. Therefore, in the descent stop step, in which descent of the upper mold LCM2 in the Z direction is stopped, alignment of the punches PNC and the dies DIE in the X direction shown in FIG. 18 may be continued.

According to this embodiment, the descent stop step included in the alignment step prevents the punches PNC from biting into the leads LD before the completion of alignment and becoming unable to move in the X direction. Consequently, at the start of cutting, the clearance distances CLR1 and CLR2 can be substantially equal as shown in FIG. 19. Even in the descent stop step, the leads LD are already deformed and the reactive forces RF1, RF2, ORF1, and ORF2 are applied as shown in FIG. 19. However, when the clearance distances CLR1 and CLR2 are substantially equal, the reactive forces RF1 and RF2 are substantially equal and the reactive forces ORF1 and ORF2 are substantially equal. Therefore, the reactive forces RF1, RF2, ORF1, and ORF2 are summed up and a balanced state is attained.

Although FIG. 19 shows a case that the reactive forces RF1, RF2, ORF1, and ORF2 are equal, the reactive forces RF1 and ORF1 may be unequal or the reactive forces RF2 and ORF2 may be unequal.

In this embodiment, descent of the upper mold LCM2 is temporarily stopped in order to perform alignment as described above. However, the descent stop step (FIG. 13) maybe omitted. For example, if the speed at which the upper mold LCM2 moves down toward the lower mold LCM1 (FIG. 14) is slow enough, alignment can be finished before the start of cutting.

In order to improve the working efficiency in the lead cutting step, the descent speed may be changed as follows: the speed is relatively slow before alignment and relatively high after alignment. Specifically, in a variation of this embodiment, in the step of deforming leads (FIG. 13), the upper mold LCM2 may be moved toward the lower mold LCM1 at a first speed and in the step of cutting leads, the upper mold LCM2 may be moved toward the lower mold LCM1 at a second speed higher than the first speed.

In the alignment step, before cutting of the leads LD by the punches PNC is started, an end face LDh1 as described earlier in reference to FIG. 5 is made in the step of deforming leads LD. The end face LDh1 shown in FIG. 5 is a deformed face made by pressing and deforming a lead LD by a lead cutting punch PNC in the alignment step included in the lead cutting step. The formation of end faces LDh1 is continued until just before shearing of leads LD is started in the lead cutting step.

When the punches PNC descend while moving in the X direction as in this embodiment, they hardly bite into the leads LD. Therefore, the time to start cutting leads LD can be delayed so as to increase the height H1 from the lower surface LDb of each lead LD to the border line BL1 as shown in FIG. 5.

Next, in the step of cutting leads (FIG. 13), the leads LD1 and LD2 are simultaneously cut by the lower mold LCM1 and upper mold LCM2 shown in FIG. 14. Specifically, the upper mold LCM2 (FIG. 14) temporarily stopped in the descent stop step (FIG. 13) is moved (lowered) toward the lower mold LCM1 (FIG. 14) again. At this time, the punches PNC1 and PNC2 shown in FIG. 19 further move down. Consequently the leads LD1 and LD2 are sandwiched between the punches PNC and the dies DIE and cut simultaneously.

As shown in FIG. 13, the step of cutting leads includes the step of making a shear surface to make an end face LDh3 as a shear surface and the step of making a fracture surface to make an end face LDh2 as a fracture surface.

In the step of making a shear surface, while the upper surfaces LDt of the leads LD1 and LD2 each remain continuous or uncut as shown in FIG. 20, the punches PNC1 and PNC2 bite into the leads LD1 and LD2 and shear them respectively. As a result of this shearing action, the base material BSM1 of each lead LD is sheared and an end face LDh3 continuous with the deformed end face LDh1 is formed as shown in FIG. 5. Also the metal coating MC is dragged and attached to the end face LDh3 by the punch PNC (FIG. 20).

As the punch PNC shown in FIG. 20 further moves down, the uncut portion of the lead LD becomes thinner. As the uncut portion of the lead LD becomes thinner, cracking occurs in the uncut portion of the lead LD due to the pressing force applied by the punch PNC. As cracking progresses, the uncut portion fractures and an end face LDh2 as a fracture surface is formed as shown in FIG. 5.

The end face LDh3 is a shear surface made by pressing and shearing the lead LD by the punch of the mold in the step of cutting leads. The end face LDh2 is a fracture surface made by pressing the lead LD and fracturing a portion thereof adjacent to the upper surface LDt by the punch of the mold in the step of cutting leads.

In this embodiment, the punch PNC moves down while moving in the X direction as described above and the time to start cutting the lead LD can be delayed so as to increase the height H1 from the lower surface LDb of the lead LD to the border line BL1 as shown in FIG. 5. Consequently, the height H4 from the border line BL2 between the end face LDh3 made by shearing the lead LD and the end face LDh2 as a fracture surface to the lower surface LDb as shown in FIG. 5 can be increased.

In this embodiment, the height H4 from the lower surface LDb of the lead LD to the border line BL2 is larger than the height H2 from the border line BL2 to the upper surface LDt. In other words, the height H4 from the lower surface LDb of the lead LD to the border line BL2 is more than one half of the thickness T1 of the lead LD (distance between the upper surface LDt and lower surface LDb). As described earlier, when the height H4 is large, the solder SD (FIG. 5) easily spreads up to more than one half the thickness T1 of the lead LD, so that the mounting strength is increased.

Furthermore, in the lead cutting step, when the bottom of the punch PNC and the top of the die DIE are flush with each other, contact between the punch PNC and the die DIE might damage the lead cutter LC1 (FIG. 14). In order to prevent this, it is necessary to make the sum of the clearance distances CLR1 and CLR2 shown in FIG. 21 larger than the sum of the gap distances SPL1 and SPL2. As described above, in this embodiment, the sum of the gap distances SPL1 and SPL2 shown in FIG. 15 is, for example, 20 μm or more. Thus, it is desirable that the sum of the clearance distances CLR1 and CLR2 shown in FIG. 21 be at least larger than the sum of the gap distances SPL1 and SPL2 shown in FIG. 15.

If the clearance distance CLR1 or CLR2 is too large at the time of cutting, it would be difficult to perform cutting work stably. Consequently, it would be difficult to make the tip end stably have the configuration as described above in reference to FIG. 5.

However, according to this embodiment, in the lead cutting step, alignment is performed by the self-alignment method before the start of cutting work. This suppresses the possibility that either of the clearance distances CLR1 and CLR2 is extremely large at the time of cutting. Therefore, the sum of the clearance distances CLR1 and CLR2 can be increased.

However, even when, as in this embodiment, the leads LD are cut after the clearance distances CLR1 and CLR2 become substantially equal, from the viewpoint of stability in cutting work it is desirable that the sum of the clearance distances CLR1 and CLR2 be small.

In this embodiment, the dimensional tolerance of distance PNL1 between neighboring punches PNC shown in FIG. 14 is not more than one half of the sum of the gap distances SPL1 and SPL2 shown in FIG. 15. The dimensional tolerance of the lower mold LCM1 and posts PST fixed on the support SPS shown in FIG. 14 is not more than one half of the sum of the gap distances SPL1 and SPL2 shown in FIG. 15. Thus, in this embodiment, the sum of clearance distances CLR1 and CLR2 shown in FIG. 21 is not more than twice the sum of the gap distances SPL1 and SPL2 shown in FIG. 15.

As mentioned above, in this embodiment, the dimensional tolerance of the lower mold LCM1 and posts PST fixed on the support SPS shown in FIG. 14, and the dimensional tolerance of distance PNL1 between neighboring punches PNC shown in FIG. 14 are small enough to suppress an increase in the sum of the clearance distances CLR1 and CLR2 shown in FIG. 21. Therefore, in the lead cutting step according to this embodiment, a plurality of leads LD can be cut under almost the same cutting conditions. As a consequence, the leads LD are each stably cut so as to have the same tip end configuration.

In addition, in this embodiment, as shown in FIG. 21, the leads LD are cut while the clearance distances CLR1 and CLR2 are substantially equal. Therefore, in the step of placing a substrate (FIG. 13), the lengths of the leads LD after cutting can be equalized by increasing the accuracy in alignment between the lower mold LCM1 (FIG. 14) and the lead frame LF. Specifically, the length of the outer lead part OLD of the lead LD1 after cutting can be substantially equal to the length of the outer lead part OLD of the lead LD2 after cutting.

In addition, as described above, in this embodiment, among the leads LD shown in FIG. 10, the leads LD1 and LD2 extending in the X direction are first cut simultaneously and then the leads LD3 and LD4 extending in the Y direction are cut simultaneously. After the step of making a fracture surface (FIG. 13) is finished, the leads LD3 and LD4 extending in the Y direction as shown in FIG. 10 are cut simultaneously. The steps from the step of placing a substrate to the step of making a fracture surface (FIG. 13) are carried out again to cut the leads LD3 and LD4 simultaneously and descriptions of these steps are not repeated here.

Next, in the step of reshaping leads (FIG. 13), bending work is done on each of the leads LD so that the outer lead part OLD of the lead LD protruding from the side surface MRs of the sealing member MR is bended downward as illustrated in FIG. 2. There is no limitation on the bending method. For example, the lead LD may be pinched by a mold for bending (not shown) and bended by press work.

FIG. 13 shows that the step of reshaping leads is carried out after the step of cutting leads. However, alternatively, the step of cutting leads may be carried out after the step of reshaping leads. In this case, each lead LD is cut so that its outer lead part is longer than the outer lead part OLD of the lead LD shown in FIG. 2, and then the lead LD is reshaped. Then, the tip of the outer lead part OLD of the reshaped lead LD is cut again so that the end faces LDh1, LDh2, and LDh3 are formed as shown in FIG. 5.

### <Variations>

The invention made by the present inventors has been so far explained concretely in reference to the preferred embodiment thereof. However, the invention is not limited thereto and it is obvious that these details may be modified in various ways without departing from the gist thereof. Also, several variations of the above embodiment have been described above. Next, typical variations other than the variations described above will be described.

### <Variation 1>

In the above embodiment, among the leads LD shown in FIG. 10, the leads LD1 and LD2 extending in the X direction are first cut simultaneously and then the leads LD3 and LD4 extending in the Y direction are cut simultaneously. However, as a variation, among the leads LD shown in FIG. 10, the leads LD1 and LD2 extending in the X direction and the leads LD3 and LD4 extending in the Y direction may be cut simultaneously. In this case, the time required for the lead cutting step is shorter than in the above embodiment, so that the manufacturing efficiency is further improved.

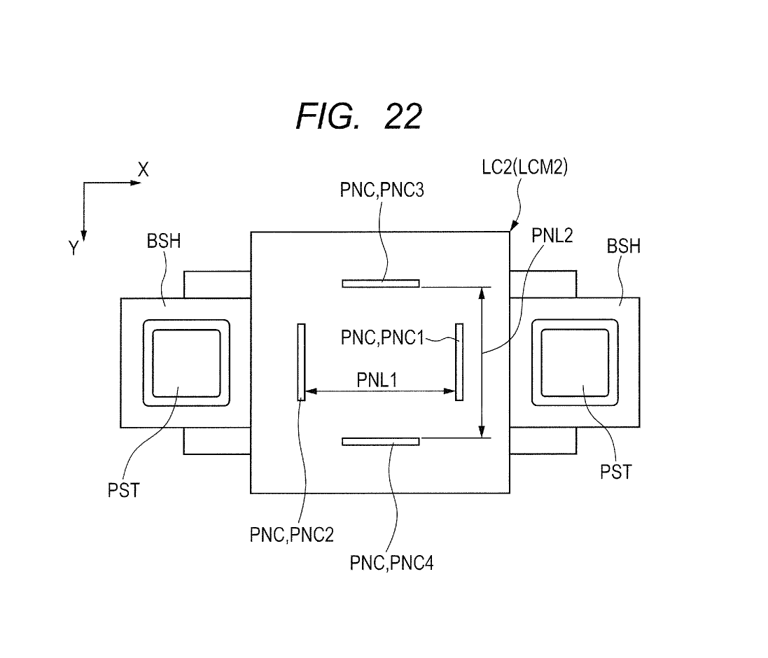

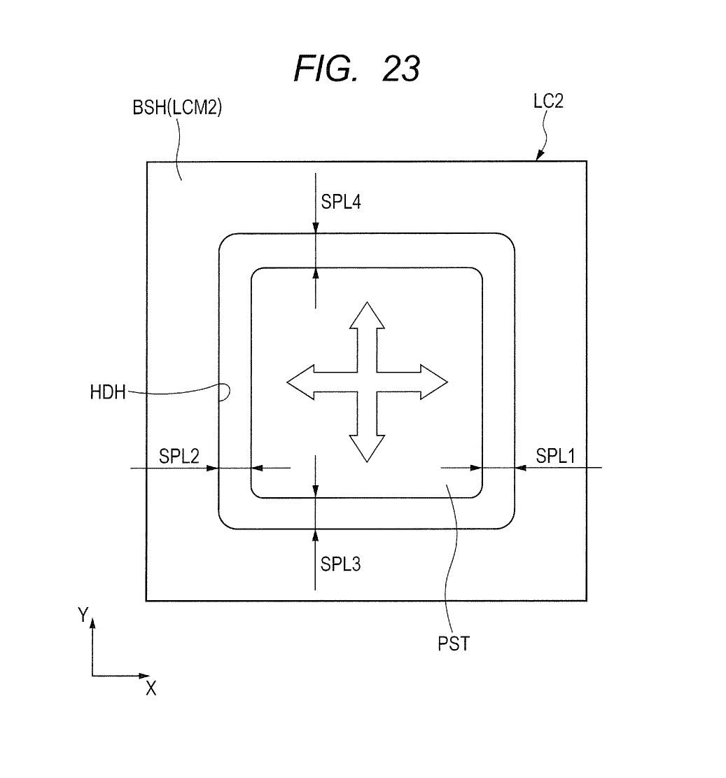

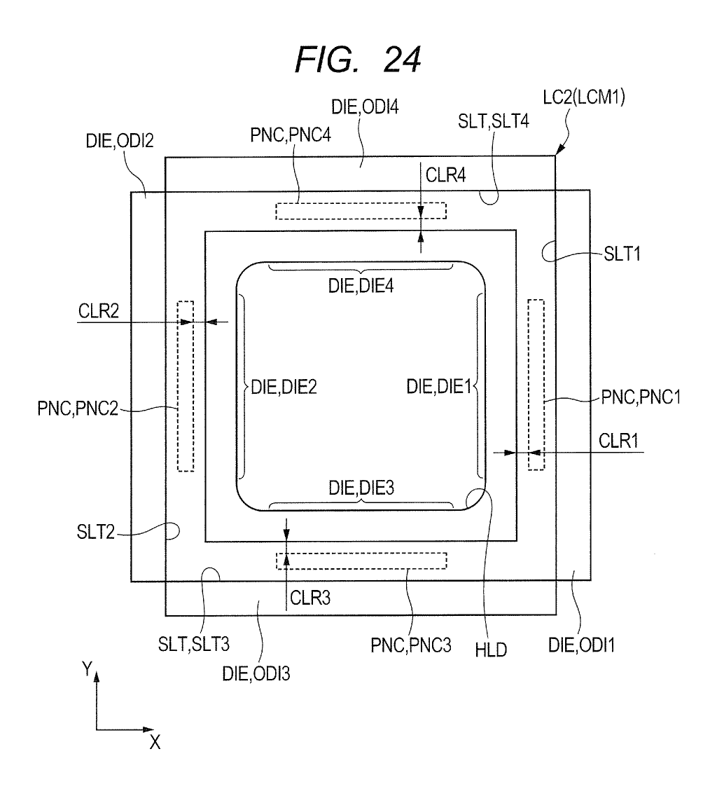

Next, how the leads LD protruding from the four sides of the sealing member MR are cut simultaneously will be described. FIG. 22 is a bottom plan view of the upper mold of a lead cutter as a variation of the lead cutter shown in FIG. 14, in which a plurality of punches are fixed on the bottom of the upper mold. FIG. 23 is a plan view showing the positional relation between the post and bush shown in FIG. 22 as a variation of the one shown in FIG. 15. FIG. 24 is an enlarged plan view showing the planar positional relation between the punches and the dies with the upper mold (FIG. 22) placed over the lower mold.

In FIG. 24, the punches PNC are indicated by dotted lines in order to show the planar positional relation between the punches PNC and the dies DIE.

As shown in FIG. 22, the upper mold LCM2 of the lead cutter LC2 in this variation is different from the upper mold LCM2 of the lead cutter LC1 shown in FIG. 14 in that it has not only punches PNC1 and PNC2 facing each other in the X direction but also punches PNC3 and PNC4 facing each other in the Y direction. In the lead cutting step in this variation, the punch PNC1 cuts leads LD1 (FIG. 10), the punch PNC2 cuts leads LD2 (FIG. 10), the punch PNC3 cuts leads LD3 (FIG. 10), and the punch PNC4 cuts leads LD4 (FIG. 10).

Also, as shown in FIG. 24, the lower mold LCM1 of the lead cutter LC2 in this variation is different from the lower mold LCM1 of the lead cutter LC1 shown in FIG. 14, in the following point. The lower mold LCM1 of the lead cutter LC2 has not only dies DIE1 and DIE2 facing each other in the X direction through the housing part HLD of the sealing member MR (FIG. 10), but also dies DIE3 and DIE4 facing each other in the Y direction through the housing part HLD. The dies DIE1, DIE2, DIE3, and DIE4 face other dies ODI1, ODI2, ODI3, and ODI4 through slits SLT1, SLT2, SLT3, and SLT4, respectively. The punches PNC1, PNC2, PNC3, and PNC4 are designed to be inserted in the slits SLT1, SLT2, SLT3, and SLT4 respectively.

As shown in FIG. 23, in the upper mold LCM2 of the lead cutter LC2 in this variation, the gap relation between the post PST and bush BSH is different from that in the above embodiment as described in reference to FIG. 15. Specifically, the sum of gap distances SPL3 and SPL4 shown in FIG. 23 is not less than twice the dimensional tolerance (for example, ±3 μm) of distance PNL2 between neighboring punches PNC in the Y direction as shown in FIG. 22. In the example shown in FIG. 23, the sum of the gap distances SPL3 and SPL4 is, for example, 20 μm or more.

The sum of the gap distances SPL1 and SPL2 shown in FIG. 23 is the same as in the above embodiment. Specifically, the sum of the gap distances SPL1 and SPL2 is not less than twice the dimensional tolerance (for example, ±3 μm) of the distance PNL1 between neighboring punches PNC as shown in FIG. 22. In the example shown in FIG. 23, the sum of the gap distances SPL1 and SPL2 is substantially equal to the sum of the gap distances SPL3 and SPL4 and, for example, it is 20 μm or more.

In the above embodiment, the self-alignment method is achieved by increasing the margin for the range of movement in the X direction. On the other hand, as schematically shown by arrows in FIG. 23, the self-alignment method can also be achieved by increasing the margins for the range of movement in both the X and Y directions on the X-Y plane.

When the self-alignment method in the above embodiment which uses the reactive forces generated by deforming leads LD is used in this variation, it is easy to understand the method by considering the reactive force component in the X direction and the reactive force component in the Y direction as shown in FIG. 24 separately. The reactive force component in the X direction, which is used to perform alignment to equalize the clearance distances CLR1 and CLR2 shown in FIG. 24, is generated mainly by deforming the leads LD1 and LD2 shown in FIG. 10. On the other hand, the reactive force component in the Y direction, which is used to perform alignment to equalize the clearance distances CLR3 and CLR4 shown in FIG. 24, is generated mainly by deforming the leads LD3 and LD4 shown in FIG. 10.

In this variation, the sum of the gap distances SPL1 and SPL2 shown in FIG. 23 is not less than twice the dimensional tolerance of the distance PNL1 between neighboring punches PNC1 and PNC2 in the X direction as shown in FIG. 22. Consequently, in the alignment step included in the lead cutting step, alignment can be performed so that in the X direction the clearance distance CLR1 from the punch PNC1 to the die DIE1 is equal to the clearance distance CLR2 from the punch PNC2 to the die DIE2.

Also, in this variation, the sum of the gap distances SPL3 and SPL4 shown in FIG. 23 is not less than twice the dimensional tolerance of the distance PNL2 between neighboring punches PNC3 and PNC4 in the Y direction as shown in FIG. 22. Consequently, in the alignment step included in the lead cutting step, alignment can be performed so that in the Y direction the clearance distance CLR3 from the punch PNC3 to the die DIE3 is equal to the clearance distance CLR4 from the punch PNC4 to the die DIE4.

As a result, in the lead cutting step, the leads LD1, LD2, LD3, and LD4 shown in FIG. 10 can be cut simultaneously under the same cutting conditions. For the purpose of equalizing the cutting conditions for the leads LD1, LD2, LD3, and LD4, it is desirable to perform alignment so that the clearance distances CLR1, CLR2, CLR3, and CLR4 may be considered to be substantially equal.

This variation is the same as the above embodiment except the above difference, so the same descriptions are not repeated.

For easy understanding of the positions of the gap distances SPL1, SPL2, SPL3, and SPL4, FIGS. 15 and 23 show an example that the planar shape of the post PST and the opening shape of the through hole HDH of the bush BSH are quadrangular. However, they may have another shape; for example, they may be circular or oval.

### <Variation 2>

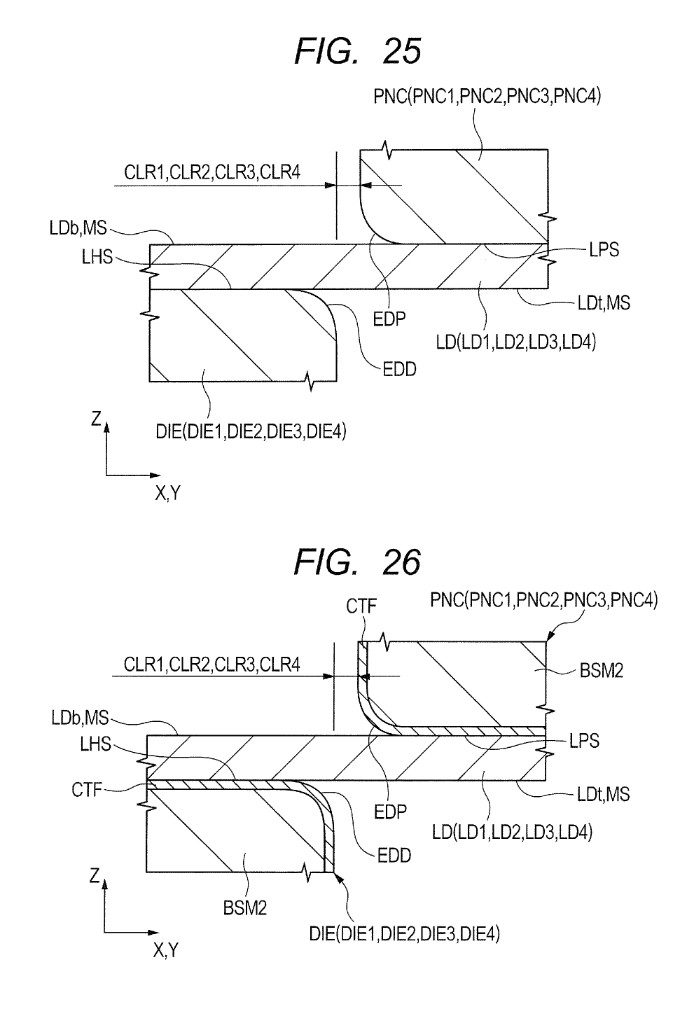

In a second variation, an end of the lead holding surface of the die and an end of the pressing surface of the punch are chamfered. FIG. 25 is an enlarged sectional view showing an end of the lead holding surface of a die and an end of the pressing surface of a punch, in which the die and punch are modified forms of the die and punch shown in FIGS. 16 to 21. FIG. 26 is an enlarged sectional view showing modified forms of the die and punch shown in FIG. 25.

In the modified forms shown in FIGS. 25 and 26, the die DIE1 has a lead holding surface (first supporting surface) LHS for supporting leads LD1 and an end (first supporting end) EDD located outside the lead holding surface LHS. The die DIE2 has a lead holding surface (second supporting surface) LHS for supporting leads LD2 and an end (second supporting end) EDD located outside the lead holding surface LHS. The die DIE3 has a lead holding surface (third supporting surface) LHS for supporting leads LD3 and an end (third supporting end) EDD located outside the lead holding surface LHS. The die DIE4 has a lead holding surface (fourth supporting surface) LHS for supporting leads LD4 and an end (fourth supporting end) EDD located outside the lead holding surface LHS.

The punch PNC1 has a lead pressing surface (first pressing surface) LPS for pressing leads LD1 and an end (first pressing end) EDP located outside the lead pressing surface LPS. The punch PNC2 has a lead pressing surface (second pressing surface) LPS for pressing leads LD2 and an end (second pressing end) EDP located outside the lead pressing surface LPS. The punch PNC3 has a lead pressing surface (third pressing surface) LPS for pressing leads LD3 and an end (third pressing end) EDP located outside the lead pressing surface LPS. The punch PNC4 has a lead pressing surface (fourth pressing surface) LPS for pressing leads LD4 and an end (fourth pressing end) EDP located outside the lead pressing surface LPS.

The ends EDD and EDP are chamfered. In the examples shown in FIGS. 25 and 26, round chamfering is done on the ends EDD and EDP. According to the examination by the present inventors, it is desirable that the size of the rounded surface be in the range from 3 μm to 20 μm. In the above embodiment, the margin for the range of movement of the punch PNC is large in the X direction. In Variation 1, the margin for the range of movement of the punch PNC is large in the X and Y directions. Therefore, when the ends EDD and EDP are chamfered, the punch PNC and the die DIE are less likely to contact each other than when they are not chamfered. For example, when the chamfered portion of the die DIE and the chamfered portion of the punch PNC overlap in the lead thickness direction, as the punch moves down, it is easier for the punch to move in the direction in which the punch PNC and the die DIE are away from each other. Thus, when the range of movement is increased and the ends EDD and EDP are chamfered as in this variation, the possibility that the lead cutter may be damaged due to contact between the punch PNC and the die DIE is reduced.

When the punch PNC and the die DIE are less likely to contact each other as mentioned above, the sum of the clearance distances CLR1 and CLR2 and the sum of the clearance distances CLR3 and CLR4 can be decreased.

In the example shown in FIG. 26, the dies DIE1, DIE2, DIE3, and DIE4 and the punches PNC1, PNC2, PNC3, and PNC4 each include a base material BSM2 and a coating film CTF covering the base material BSM2. The coating film CTF is a protective film which suppresses wear of the base material BSM2 and the hardness of the coating film CTF is higher than the hardness of the base material BSM2.

Therefore, the end EDP of the punch PNC and the end EDD of the die DIE, where friction easily occurs during cutting work, are covered by the coating film CTF.

Since the surface of the base material BSM2 is covered by the coating film CTF, wear of the die DIE and the punch PNC is retarded. This means that the period in which leads LD are stably cut under the same cutting conditions is prolonged.

### <Variation 3>

In the above embodiment, the self-alignment method which uses the reactive forces of leads LD is employed to align the upper mold LCM2 and lower mold LCM1 in the lead cutting step as described above. However, another alignment method which does not use the reactive forces used in the above embodiment may be adopted provided that the clearance distances CLR1 and CLR2 become substantially equal as illustrated in FIG. 19.

One such method may be that an alignment mark (not shown) is made on the lower mold LCM1 and the leads LD are pressed while the upper mold LCM2 and lower mold LCM1 are being aligned according to the information on the position of the alignment mark.

However, the self-alignment method employed in the above embodiment is particularly desirable in the sense that the method allows accurate alignment without a complicated mechanism including an alignment mark reader and a device for controlling the direction of movement of the upper mold LCM2.

### <Variation 4>

The above embodiment assumes that the semiconductor device is a QFP semiconductor device PKG1 which has leads protruding from the four sides of a quadrangular sealing member in plan view. However, the above technique may be widely applied to semiconductor devices which have a plurality of leads protruding from two opposite sides of a sealing member for sealing a semiconductor chip. For example, it may be applied to an SOP (Small Outline Package) which has a plurality of leads protruding from the opposite long sides of the four sides of a rectangular sealing member.

In this case, the need for repeating some steps as indicated by the dotted line in FIG. 13 in the lead cutting step of the above embodiment can be eliminated.

### <Variation 5>

Further, for example, several variations have been described above. Any combination of the variations described above may be adopted.

Some details of the embodiment described above are given below.
(1) A method for manufacturing a semiconductor device, including the steps of: (a) providing a lead frame including a semiconductor chip, a plurality of leads each being electrically coupled to the semiconductor chip and having an inner lead part and an outer lead part, and a sealing member sealing the inner lead parts of the leads; and (b) partially cutting the outer lead parts of the leads, exposed from the sealing member to cut the leads off the lead frame, in which in plan view the sealing member has a first side, a second side opposite to the first side, a third side crossing the first side, and a fourth side opposite to the third side, in which the leads include a first lead protruding from the first side of the sealing member and extending in a first direction, a second lead protruding from the second side of the sealing member and extending in the first direction, a third lead protruding from the third side of the sealing member and extending in a second direction perpendicular to the first direction, and a fourth lead protruding from the fourth side of the sealing member and extending in the second direction, in which the first lead, the second lead, the third lead, and the fourth lead each have a lower surface including a portion which, with the semiconductor device mounted on a mounting board, faces a mounting surface of the mounting board for mounting the semiconductor device, and an upper surface opposite to the lower surface, in which the step (b) includes the steps of: (b1) supporting the upper surface of the first lead, the upper surface of the second lead, the upper surface of the third lead, and the upper surface of the fourth lead by a first mold; (b2) after the step (b1), making a second mold move toward and contact the lower surface of the first lead, the lower surface of the second lead, the lower surface of the third lead, and the lower surface of the fourth lead; (b3) after the step (b2), aligning the second mold with the first mold; (b4) after the step (b3), cutting the first lead, the second lead, the third lead, and the fourth lead simultaneously using the first mold and the second mold, in which the first mold used in the step (b) has a first die for supporting the first lead, a second die for supporting the second lead, a third die for supporting the third lead, and a fourth die for supporting the fourth lead, in which the second mold used in the step (b) has a first punch located outside the first die in the first direction to cut the first lead, a second punch located outside the second die in the first direction to cut the second lead, a third punch located outside the third die in the second direction to cut the third lead, and a fourth punch located outside the fourth die in the second direction to cut the fourth lead, and in which in the step (b3), alignment is performed so that a first clearance distance from the first punch to the first die and a second clearance distance from the second punch to the second die are equal in the first direction and a third clearance distance from the third punch to the third die and a fourth clearance distance from the fourth punch to the fourth die are equal in the second direction.
(2) The method for manufacturing a semiconductor device as described above in (1), in which the step (b3) includes the steps of: (b31) moving the second mold toward the first mold until the first lead, the second lead, the third lead, and the fourth lead are partially deformed; and (b32) temporarily stopping movement of the second mold toward the first mold, and in which in the step (b4), the stopped second mold is moved again toward the first mold to cut the first lead, the second lead, the third lead, and the fourth lead simultaneously.
(3) The method for manufacturing a semiconductor device as described above in (1), in which the second mold has a rail holder which slides along a guide rail extending in the thickness direction of the lead frame, and in which the sum of gap distances between the guide rail and the rail holder in the first direction is not less than twice the dimensional tolerance of distance between the first punch and the second punch.
(4) The method for manufacturing a semiconductor device as described above in (3), in which the sum of the first clearance distance and the second clearance distance is not more than twice the sum of the gap distances and the sum of the third clearance distance and the fourth clearance distance is not more than twice the sum of the gap distances.
(5) The method for manufacturing a semiconductor device as described above in (1), in which a solder coating is made on a surface of each of the outer lead parts of the first lead and the second lead in the lead frame provided in the step (a).
(6) The method for manufacturing a semiconductor device as described above in (1), in which the first die has a first supporting surface for supporting the first lead and a first supporting end located outside the first supporting surface, in which the second die has a second supporting surface for supporting the second lead and a second supporting end located outside the second supporting surface, in which the third die has a third supporting surface for supporting the third lead and a third supporting end located outside the third supporting surface, in which the fourth die has a fourth supporting surface for supporting the fourth lead and a fourth supporting end located outside the fourth supporting surface, in which the first punch has a first pressing surface for pressing the first lead and a first pressing end located inside the first pressing surface, in which the second punch has a second pressing surface for pressing the second lead and a second pressing end located inside the second pressing surface, in which the third punch has a third pressing surface for pressing the third lead and a third pressing end located inside the third pressing surface, in which the fourth punch has a fourth pressing surface for pressing the fourth lead and a fourth pressing end located inside the fourth pressing surface, and in which the first supporting end, the second supporting end, the third supporting end, the fourth supporting end, the first pressing end, the second pressing end, the third pressing end, and the fourth pressing end are chamfered.
(7) The method for manufacturing a semiconductor device as described above in (6), in which the first die, the second die, the third die, the fourth die, the first punch, the second punch, the third punch, and the fourth punch each have abase material and a first coating covering the base material, in which the hardness of the first coating is higher than the hardness of the base material, and in which the first supporting end, the second supporting end, the third supporting end, the fourth supporting end, the first pressing end, the second pressing end, the third pressing end, and the fourth pressing end are each covered by the first coating.
(8) The method for manufacturing a semiconductor device as described above in (1), in which ends of the first lead, the second lead, the third lead, and the fourth lead which are cut in the step (b) each have a first side face continuous with the lower surface, a second side face continuous with the upper surface, and a third side face continuous with the first side face through a first border line and continuous with the second side face through a second border line, in which the first side face is a deformed surface made by pressing and deforming the first lead, the second lead, the third lead, and the fourth lead by the first punch, the second punch, the third punch, and the fourth punch of the second mold in the step (b3), in which the third side face is a shear surface made by pressing and shearing the first lead, the second lead, the third lead, and the fourth lead by the first punch, the second punch, the third punch, and the fourth punch of the second mold in the step (b4), in which the second side face is a fracture surface made by pressing the first lead, the second lead, the third lead, and the fourth lead by the first punch, the second punch, the third punch, and the fourth punch of the second mold and fracturing portions thereof adjacent to the upper surface in the step (b4), and in which the height from the lower surface to the second border line is larger than the height from the second border line to the upper surface.
(9) The method for manufacturing a semiconductor device as described above in (1), in which ends of the first lead, the second lead, the third lead, and the fourth lead which are cut in the step (b) each have a first side face continuous with the lower surface, a second side face continuous with the upper surface, and a third side face continuous with the first side face through a first border line and continuous with the second side face through a second border line, in which the first side face is a deformed surface made by pressing and deforming the first lead, the second lead, the third lead, and the fourth lead by the first punch, the second punch, the third punch, and the fourth punch of the second mold in the step (b3), in which the third side face is a shear surface made by pressing and shearing the first lead, the second lead, the third lead, and the fourth lead by the first punch, the second punch, the third punch, and the fourth punch of the second mold in the step (b4), in which the second side face is a fracture surface made by pressing the first lead, the second lead, the third lead, and the fourth lead by the first punch, the second punch, the third punch, and the fourth punch of the second mold and fracturing portions thereof adjacent to the upper surface in the step (b4), and in which the height from the lower surface to the first border line is larger than the height from the first border line to the second border line.

What is claimed is:

1. A method for manufacturing a semiconductor device, comprising the steps of:
(a) providing a lead frame including:
a semiconductor chip,
a plurality of leads each being electrically coupled to the semiconductor chip and having an inner lead part and an outer lead part, and
a sealing member sealing the inner lead parts of the leads; and
(b) partially cutting the outer lead parts of the leads, exposed from the sealing member to cut the leads off the lead frame,
wherein in plan view the sealing member has a first side and a second side opposite to the first side,
wherein the leads include a first lead protruding from the first side of the sealing member and extending in a first direction and a second lead protruding from the second side of the sealing member and extending in the first direction,
wherein the first lead and the second lead each have a lower surface including a portion which, with the semiconductor device mounted on a mounting board, faces a mounting surface of the mounting board for mounting the semiconductor device, and an upper surface opposite to the lower surface,
the step (b) comprising the steps of:
(b1) supporting the upper surface of the first lead and the upper surface of the second lead by a first mold;
(b2) after the step (b1), making a second mold move toward and contact the lower surface of the first lead and the lower surface of the second lead;
(b3) after the step (b2), aligning the second mold with the first mold;
(b4) after the step (b3), cutting the first lead and the second lead simultaneously using the first mold and the second mold,
wherein the first mold used in the step (b) has a first die for supporting the first lead and a second die for supporting the second lead,
wherein the second mold used in the step (b) has a first punch located outside the first die in the first direction to cut the first lead and a second punch located outside the second die in the first direction to cut the second lead, and
wherein in the step (b3), alignment is performed so that a first clearance distance from the first punch to the first die and a second clearance distance from the second punch to the second die are equal.

2. The method for manufacturing a semiconductor device according to claim 1, the step (b3) comprising the steps of:
(b31) moving the second mold toward the first mold until the first lead and the second lead are partially deformed; and
(b32) temporarily stopping movement of the second mold toward the first mold,
wherein in the step (b4), the stopped second mold is moved again toward the first mold to cut the first lead and the second lead simultaneously.

3. The method for manufacturing a semiconductor device according to claim 1,
wherein the second mold has a rail holder which slides along a guide rail extending in a thickness direction of the lead frame, and
wherein a sum of gap distances between the guide rail and the rail holder in the first direction is not less than twice dimensional tolerance of distance between the first punch and the second punch.

4. The method for manufacturing a semiconductor device according to claim 3, a sum of the first clearance distance and the second clearance distance is not more than twice the sum of the gap distances.

5. The method for manufacturing a semiconductor device according to claim 1, wherein a solder coating is made on a surface of each of the outer lead parts of the first lead and the second lead in the lead frame provided in the step (a).

6. The method for manufacturing a semiconductor device according to claim 1,
wherein the first die has a first supporting surface for supporting the first lead and a first supporting end located outside the first supporting surface,
wherein the second die has a second supporting surface for supporting the second lead and a second supporting end located outside the second supporting surface,
wherein the first punch has a first pressing surface for pressing the first lead and a first pressing end located inside the first pressing surface,
wherein the second punch has a second pressing surface for pressing the second lead and a second pressing end located inside the second pressing surface, and
wherein the first supporting end, the second supporting end, the first pressing end, and the second pressing end are chamfered.

7. The method for manufacturing a semiconductor device according to claim 6,
wherein the first die, the second die, the first punch, and the second punch each have a base material and a first coating covering the base material,
wherein hardness of the first coating is higher than hardness of the base material, and
wherein the first supporting end, the second supporting end, the first pressing end, and the second pressing end are each covered by the first coating.

8. The method for manufacturing a semiconductor device according to claim 1,
wherein ends of the first lead and the second lead which are cut in the step (b) each have a first side face continuous with the lower surface, a second side face continuous with the upper surface, and a third side face continuous with the first side face through a first border line and continuous with the second side face through a second border line,
wherein the first side face is a deformed surface made by pressing and deforming the first lead and the second lead by the first punch and the second punch of the second mold in the step (b3),
wherein the third side face is a shear surface made by pressing and shearing the first lead and the second lead by the first punch and the second punch of the second mold in the step (b4),
wherein the second side face is a fracture surface made by pressing the first lead and the second lead by the first punch and the second punch of the second mold and fracturing portions thereof adjacent to the upper surface in the step (b4), and
wherein height from the lower surface to the second border line is larger than height from the second border line to the upper surface.

9. The method for manufacturing a semiconductor device according to claim 1,
wherein ends of the first lead and the second lead which are cut in the step (b) each have a first side face continuous with the lower surface, a second side face continuous with the upper surface, and a third side face continuous with the first side face through a first border line and continuous with the second side face through a second border line,
wherein the first side face is a deformed surface made by pressing and deforming the first lead and the second lead by the first punch and the second punch of the second mold in the step (b3),
wherein the third side face is a shear surface made by pressing and shearing the first lead and the second lead by the first punch and the second punch of the second mold in the step (b4),
wherein the second side face is a fracture surface made by pressing the first lead and the second lead by the first punch and the second punch of the second mold and fracturing portions thereof adjacent to the upper surface in the step (b4), and
wherein height from the lower surface to the first border line is larger than height from the first border line to the second border line.

10. The method for manufacturing a semiconductor device according to claim 1,
wherein in the step (b3), the second mold is moved toward the first mold at a first speed, and
wherein in the step (b4), the second mold is moved toward the first mold at a second speed higher than the first speed.

11. The method for manufacturing a semiconductor device according to claim 1,
wherein in plan view, the sealing member has a third side crossing the first side and a fourth side opposite to the third side,
wherein the leads include a third lead protruding from the third side of the sealing member and extending in a second direction perpendicular to the first direction and a fourth lead protruding from the fourth side of the sealing member and extending in the second direction,
wherein the third lead and the fourth lead each have a lower surface including a portion which, with the semiconductor device mounted on the mounting board, faces the mounting surface of the mounting board for mounting the semiconductor device, and an upper surface opposite to the lower surface,
the step (b) comprising the steps of:
(b1) supporting the upper surface of the first lead, the upper surface of the second lead, the upper surface of the third lead, and the upper surface of the fourth lead by the first mold;
(b2) after the step (b1), making the second mold move toward and contact the lower surface of the first lead, the lower surface of the second lead, the lower surface of the third lead, and the lower surface of the fourth lead;
(b3) after the step (b2), aligning the second mold with the first mold;
(b4) after the step (b3), cutting the first lead, the second lead, the third lead, and the fourth lead simultaneously using the first mold and the second mold,
wherein the first mold used in the step (b) has the first die for supporting the first lead, the second die for supporting the second lead, a third die for supporting the third lead, and a fourth die for supporting the fourth lead,
wherein the second mold used in the step (b) has the first punch located outside the first die in the first direction to cut the first lead, the second punch located outside the second die in the first direction to cut the second lead, and a third punch located outside the third die in the second direction to cut the third lead, and a fourth punch located outside the fourth die in the second direction to cut the fourth lead,
wherein in the step (b3), alignment is performed so that the first clearance distance from the first punch to the first die and the second clearance distance from the second punch to the second die are equal in the first direction and a third clearance distance from the third punch to the third die and a fourth clearance distance from the fourth punch to the fourth die are equal in the second direction.

12. A method for manufacturing a semiconductor device, comprising the steps of:
(a) providing a lead frame including:
a semiconductor chip,
a plurality of leads each being electrically coupled to the semiconductor chip and having an inner lead part and an outer lead part, and
a sealing member sealing the inner lead parts of the leads; and
(b) partially cutting the outer lead parts of the leads, exposed from the sealing member to cut the leads off the lead frame,
wherein in plan view the sealing member has a first side and a second side opposite to the first side,
wherein the leads include a first lead protruding from the first side of the sealing member and extending in a first direction and a second lead protruding from the second side of the sealing member and extending in the first direction,
wherein the first lead and the second lead each have a lower surface including a portion which, with the semiconductor device mounted on a mounting board, faces a mounting surface of the mounting board for mounting the semiconductor device, and an upper surface opposite to the lower surface,
wherein the second mold used in the step (b) has a first punch for cutting the first lead, a second punch for cutting the second lead, and a rail holder which slides along a guide rail extending in a thickness direction of the lead frame in the step (b), and
wherein a sum of gap distances between the guide rail and the rail holder in the first direction is not less than twice dimensional tolerance of distance between the first punch and the second punch.

13. The method for manufacturing a semiconductor device according to claim 12, wherein the step (b) comprises the step of temporarily stopping the sliding movement of the second mold after the first punch and the second punch contact the first lead and the second lead respectively and before the first lead and the second lead are cut.

14. The method for manufacturing a semiconductor device according to claim 12, wherein a solder coating is made on a surface of each of the outer lead parts of the first lead and the second lead in the lead frame provided in the step (a).

15. The method for manufacturing a semiconductor device according to claim 12,
wherein the first punch has a first pressing surface for pressing the first lead and a first pressing end located inside the first pressing surface,
wherein the second punch has a second pressing surface for pressing the second lead and a second pressing end located inside the second pressing surface, and
wherein the first pressing end and the second pressing end are chamfered.

16. The method for manufacturing a semiconductor device according to claim 15,
wherein the first punch and the second punch each have a base material and a first coating covering the base material,
wherein hardness of the first coating is higher than hardness of the base material, and
wherein the first pressing end and the second pressing end are each covered by the first coating.

17. The method for manufacturing a semiconductor device according to claim 12,
wherein ends of the first lead and the second lead which are cut in the step (b) each have a first side face continuous with the lower surface, a second side face continuous with the upper surface, and a third side face continuous with the first side face through a first border line and continuous with the second side face through a second border line,
wherein the first side face is a deformed surface made by pressing and deforming the first lead and the second lead by the first punch and the second punch of the second mold in the step (b),
wherein the third side face is a shear surface made by pressing and shearing the first lead and the second lead by the first punch and the second punch of the second mold in the step (b),
wherein the second side face is a fracture surface made by pressing the first lead and the second lead by the first punch and the second punch of the second mold and fracturing portions thereof adjacent to the upper surface in the step (b), and
wherein height from the lower surface to the second border line is larger than height from the second border line to the upper surface.

18. The method for manufacturing a semiconductor device according to claim 12,
wherein ends of the first lead and the second lead which are cut in the step (b) each have a first side face continuous with the lower surface, a second side face continuous with the upper surface, and a third side face continuous with the first side face through a first border line and continuous with the second side face through a second border line,
wherein the first side face is a deformed surface made by pressing and deforming the first lead and the second lead by the first punch and the second punch of the second mold in the step (b),
wherein the third side face is a shear surface made by pressing and shearing the first lead and the second lead by the first punch and the second punch of the second mold in the step (b),
wherein the second side face is a fracture surface made by pressing the first lead and the second lead by the first punch and the second punch of the second mold and fracturing portions thereof adjacent to the upper surface in the step (b), and
wherein height from the lower surface to the first border line is larger than height from the first border line to the second border line.

19. The method for manufacturing a semiconductor device according to claim 12,
wherein in plan view, the sealing member has a third side crossing the first side and a fourth side opposite to the third side,
wherein the leads include a third lead protruding from the third side of the sealing member and extending in a second direction perpendicular to the first direction and a fourth lead protruding from the fourth side of the sealing member and extending in the second direction,
wherein the third lead and the fourth lead each have a lower surface including a portion which, with the semiconductor device mounted on the mounting board, faces the mounting surface of the mounting board for mounting the semiconductor device, and an upper surface opposite to the lower surface,
wherein the second mold used in the step (b) has the first punch for cutting the first lead, the second punch for cutting the second lead, a third punch for cutting the third lead, and a fourth punch for cutting the fourth lead, and
wherein sum of gap distances between the guide rail and the rail holder of the second mold in the second direction is not less than twice dimensional tolerance of distance between the third punch and the fourth punch.
